(19) United States
(12) Patent Application Publication
(10) Pub. No.: US 2021/0091098 A1
(43) Pub. Date: Mar. 25, 2021

(54) SEMICONDUCTOR DEVICE AND ELECTRONIC APPARATUS

(71) Applicant: SONY SEMICONDUCTOR SOLUTIONS CORPORATION, KANAGAWA (JP)

(72) Inventor: MASANORI TSUKAMOTO, KANAGAWA (JP)

(21) Appl. No.: 16/975,024

(22) PCT Filed: Apr. 1, 2019
(86) PCT No.: PCT/JP2019/014439

§ 371 Date: Aug. 21, 2020

(30) Foreign Application Priority Data
May 14, 2018 (JP) 2018-092986

(51) Int. Cl. H01L 27/11507; G11C 11/412; H01L 27/11; G11C 11/22

(52) U.S. Cl. CPC H01L 27/11507; G11C 11/221; H01L 27/1104; G11C 11/412

(57) ABSTRACT

[Overview] [Problem to be Solved] To provide a non-volatile semiconductor memory that is capable of high-speed writing or reading and suitable for high-density integration. [Solution] A semiconductor device including: a first inverting circuit including n-type FET and p-type FET; a second inverting circuit including n-type FET and p-type FET; a first ferroelectric capacitor; a second ferroelectric capacitor; and a plate line. The second inverting circuit has an output coupled to an input of the first inverting circuit and has an input coupled to an output of the first inverting circuit. The first ferroelectric capacitor has one of electrodes coupled to the input of the first inverting circuit. The second ferroelectric capacitor has one of electrodes coupled to the input of the second inverting circuit. The plate line is coupled to another of the electrodes of the first ferroelectric capacitor and another of the electrodes of the second ferroelectric capacitor.

### TECHNICAL FIELD

The present disclosure relates to a semiconductor device and an electronic apparatus.

### BACKGROUND ART

A CMOS (Complementary MOS) circuit including nMOSFET (n-type Metal-Oxide-Semiconductor Field-Effect Transistor) and pMOSFET (p-type MOSFET) provided on the same substrate is known as a circuit that consumes less power, is operable at high speed, and facilitates microfabrication and high integration.

Therefore, CMOS circuits are used in a large number of LSI (Large Scale Integration) devices. It is to be noted that such an LSI device has been commercialized in recent years as SoC (System on a Chip) that is mounted with an analog circuit, a memory, a logical circuit, and the like in one chip.

For example, Static RAM (Static Random Access Memory: SRAM) or the like is used for a memory mounted on an LSI device. The SRAM is a volatile memory that is operable at high speed, but loses the stored information when power supply is stopped. In contrast, examples of non-volatile memories that are each able to retain information even in a case where power supply is stopped include Magnetic RAM (MRAM), Ferroelectric RAM (FeRAM), or the like. It is possible to not only mount these memories on SoC, but also use the memories as memory chips alone.

The FeRAM is a semiconductor memory that stores information by using the direction of remanent polarization of a ferroelectric. It is possible to form the FeRAM, for example, as having a 1T1C (one transistor and one capacitor) structure in which a capacitor including a ferroelectric film is formed on a wiring line. The operation speed of the FeRAM is, however, lower than the operation speed of the SRAM and the FeRAM is therefore unsuitable for application to a cache memory or the like.

Accordingly, PTL 1 below discloses a semiconductor memory having a ferroelectric capacitor coupled to a storage node of SRAM including a CMOS circuit. According to the technique disclosed in PTL 1, it is possible to save information in a ferroelectric capacitor when the semiconductor memory is on standby with no power supplied. This makes it possible to provide the SRAM with non-volatility. The semiconductor memory disclosed in PTL 1 is thus able to achieve both high-speed writing or reading and non-volatility.

### CITATION LIST

### Patent Literature

PTL 1: Japanese Unexamined Patent Application Publication No. H8-180672

### SUMMARY OF THE INVENTION

### Problems to be Solved by the Invention

The above-described technique disclosed in PTL 1, however, forms a ferroelectric capacitor in the shape of a parallel plate, increasing the ferroelectric capacitor in planar area. The semiconductor memory disclosed in PTL 1 is therefore unsuitable for high-density integration.

It is therefore desired to propose a structure suitable for higher-density integration in a non-volatile semiconductor memory capable of high-speed writing or reading.

### Means for Solving the Problems

According to the present disclosure, there is provided a semiconductor device including: a first inverting circuit including n-type FET and p-type FET; a second inverting circuit including n-type FET and p-type FET; a first ferroelectric capacitor; a second ferroelectric capacitor; and a plate line. The second inverting circuit has an output coupled to an input of the first inverting circuit and has an input coupled to an output of the first inverting circuit. The first ferroelectric capacitor has one of electrodes coupled to the input of the first inverting circuit. The second ferroelectric capacitor has one of electrodes coupled to the input of the second inverting circuit. The plate line is coupled to another of the electrodes of the first ferroelectric capacitor and another of the electrodes of the second ferroelectric capacitor.

In addition, according to the present disclosure, there is provided an electronic apparatus including a semiconductor device. The semiconductor device includes a first inverting circuit including n-type FET and p-type FET, a second inverting circuit including n-type FET and p-type FET, a first ferroelectric capacitor, a second ferroelectric capacitor, and a plate line. The second inverting circuit has an output coupled to an input of the first inverting circuit and has an input coupled to an output of the first inverting circuit. The first ferroelectric capacitor has one of electrodes coupled to the input of the first inverting circuit. The second ferroelectric capacitor has one of electrodes coupled to the input of the second inverting circuit. The plate line is coupled to another of the electrodes of the first ferroelectric capacitor and another of the electrodes of the second ferroelectric capacitor.

According to the present disclosure, it is possible to couple the first ferroelectric capacitor and the second ferroelectric capacitor to a flip-flop circuit. The first ferroelectric capacitor and the second ferroelectric capacitor are each able to store information in a non-volatile manner. In addition, according to the present disclosure, it is possible to form the first ferroelectric capacitor and second ferroelectric capacitor each in a shared contact in the shape of a stacked cylinder.

### Effects of the Invention

As described above, according to the present disclosure, it is possible to provide a non-volatile semiconductor memory that is capable of high-speed writing or reading and suitable for high-density integration.

It is to be noted that the above-described effects are not necessarily limitative. Any of the effects indicated in this description or other effects that may be understood from this description may be exerted in addition to the above-described effects or in place of the above-described effects.

### BRIEF DESCRIPTION OF DRAWING

FIG. 1 is a circuit diagram illustrating an equivalent circuit of a semiconductor device according to an embodiment of the present disclosure.

FIG. 2 is a circuit diagram illustrating an equivalent circuit of a memory cell of a storage apparatus to which the semiconductor device illustrated in FIG. 1 is applied.

FIG. 3A is a schematic diagram illustrating portions of a planar structure and cross-sectional structure of the memory cell.

FIG. 3B is a schematic diagram illustrating portions of a planar structure and cross-sectional structure of the memory cell.

FIG. 4 is a schematic diagram illustrating cross sections obtain by cutting the plan views of FIGS. 3A and 3B along C-C lines.

FIG. 5 is a plan view and cross-sectional view describing a step of a method of manufacturing the memory cell.

FIG. 6 is a plan view and cross-sectional view describing a step of the method of manufacturing the memory cell.

FIG. 7 is a plan view and cross-sectional view describing a step of the method of manufacturing the memory cell.

FIG. 8 is a plan view and cross-sectional view describing a step of the method of manufacturing the memory cell.

FIG. 9 is a plan view and cross-sectional view describing a step of the method of manufacturing the memory cell.

FIG. 10 is a plan view and cross-sectional view describing a step of the method of manufacturing the memory cell.

FIG. 11 is a plan view and cross-sectional view describing a step of the method of manufacturing the memory cell.

FIG. 12 is a plan view and cross-sectional view describing a step of the method of manufacturing the memory cell.

FIG. 13 is a plan view and cross-sectional view describing a step of the method of manufacturing the memory cell.

FIG. 14 is a plan view and cross-sectional view describing a step of the method of manufacturing the memory cell.

FIG. 15 is a plan view and cross-sectional view describing a step of the method of manufacturing the memory cell.

FIG. 16 is a graph illustrating an example of hysteresis curves indicating relationships between states of a first storage node N1 and second storage node N2 and electric potentials.

FIG. 17A is an explanatory diagram describing transition of a state of the memory cell at time of restoration.

FIG. 17B is an explanatory diagram describing transition of the state of the memory cell at the time of restoration.

FIG. 17C is an explanatory diagram describing transition of the state of the memory cell at the time of restoration.

FIG. 18A is an explanatory diagram describing transition of the states of the first storage node N1 and second storage node N2 at the time of restoration.

FIG. 18B is an explanatory diagram describing transition of the states of the first storage node N1 and second storage node N2 at the time of restoration.

FIG. 18C is an explanatory diagram describing transition of the states of the first storage node N1 and second storage node N2 at the time of restoration.

FIG. 19A is an external view of an example of an electronic apparatus according to the present embodiment.

FIG. 19B is an external view of another example of the electronic apparatus according to the present embodiment.

FIG. 19C is an external view of another example of the electronic apparatus according to the present embodiment.

### MODES FOR CARRYING OUT THE INVENTION

The following describes a preferred embodiment of the present disclosure in detail with reference to the accompanying drawings. It is to be noted that, in this specification and the accompanying drawings, components that have substantially the same functional configuration are indicated by the same reference signs and redundant description thereof is thus omitted.

It is to be noted that description is given in the following order.

### 1. Overview

### 2. Structure Example

### 3. Manufacturing Method

### 4. Operation Example

### 5. Application Example

### 1. Overview

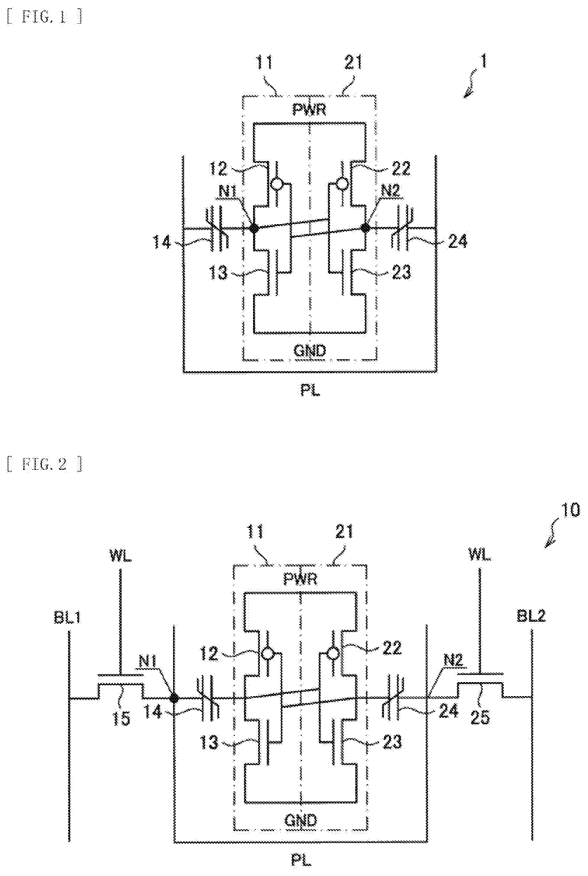

First, an overview of a semiconductor device according to an embodiment of the present disclosure is described with reference to FIG. 1. FIG. 1 is a circuit diagram illustrating an equivalent circuit of a semiconductor device according to the present embodiment.

As illustrated in FIG. 1, a semiconductor device 1 includes a first inverting circuit 11 including p-type FET (Field Effect Transistor) 12 and n-type FET 13, a second inverting circuit 21 including p-type FET 22 and n-type FET 23, a first ferroelectric capacitor 14, and a second ferroelectric capacitor 24. The semiconductor device 1 is a flip-flop circuit that is able to retain, for example, one-bit information in the state of “0” or “1”.

The first inverting circuit 11 is an inverter (NOT) circuit coupled to and provided with the p-type FET 12 and the n-type FET 13. Specifically, the first inverting circuit 11 has a power supply line PWR electrically coupled to one of the source or drain of the p-type FET 12 and has one of the source or drain of the n-type FET 13 electrically coupled to the other of the source or drain of the p-type FET 12. A ground line GND is electrically coupled to the other of the source or drain of the n-type FET 13. The gate of the p-type FET 12 and the gate of the n-type FET 13 are electrically coupled to each other.

In the first inverting circuit 11, the coupling point between the gate of the p-type FET 12 and the gate of the n-type FET 13 serves as an input and the coupling point between the other of the source or drain of the p-type FET 12 and the one of the source or drain of the n-type FET 13 serves as an output. In addition, the input of the first inverting circuit 11 is electrically coupled to the output of the second inverting circuit 21. The output of the first inverting circuit 11 is electrically coupled to the input of the second inverting circuit 21. Further, one of the electrodes of the first ferroelectric capacitor 14 is coupled to the output of the first inverting circuit 11.

The second inverting circuit 21 is an inverter (NOT) circuit coupled to and provided with the p-type FET 22 and the n-type FET 23. Specifically, the second inverting circuit 21 has the power supply line PWR electrically coupled to one of the source or drain of the p-type FET 22 and has one of the source or drain of the n-type FET 23 electrically coupled to the other of the source or drain of the p-type FET 22. The ground line GND is electrically coupled to the other of the source or drain of the n-type FET 23. The gate of the p-type FET 22 and the gate of the n-type FET 23 are electrically coupled to each other.

In the second inverting circuit 21, the coupling point between the gate of the p-type FET 22 and the gate of the n-type FET 23 serves as an input and the coupling point between the other of the source or drain of the p-type FET 22 and the one of the source or drain of the n-type FET 23 serves as an output. In addition, the input of the second inverting circuit 21 is electrically coupled to the output of the first inverting circuit 11. The output of the second inverting circuit 21 is electrically coupled to the input of the first inverting circuit 11. Further, one of the electrodes of the second ferroelectric capacitor 24 is further coupled to the output of the second inverting circuit 21.

The first ferroelectric capacitor 14 and the second ferroelectric capacitor 24 are capacitors that each include a ferroelectric film sandwiched between a pair of electrodes. The first ferroelectric capacitor 14 and the second ferroelectric capacitor 24 are each able to store information by using the direction of remanent polarization of the ferroelectric film. One of the electrodes of the first ferroelectric capacitor 14 is electrically coupled to the output of the first inverting circuit 11. The other of the electrodes of the first ferroelectric capacitor 14 is electrically coupled to a plate line PL to which any electric potential is applicable. In addition, one of the electrodes of the second ferroelectric capacitor 24 is electrically coupled to the output of the second inverting circuit 21. The other of the electrodes of the second ferroelectric capacitor 24 is electrically coupled to the plate line PL to which any electric potential is applicable.

The semiconductor device 1 feeds back the outputs of the first inverting circuit 11 and second inverting circuit 21 to the respective inputs at the time of power supply, making it possible to retain the state of “0” or “1”. Specifically, if the output of the first inverting circuit 11 is a first storage node N1 and the output of the second inverting circuit 21 is a second storage node N2, the semiconductor device 1 is able to store information in accordance with whether the first storage node N1 has a high or low electric potential and the second storage node N2 has a high or low electric potential.

In addition, when supplied with no power, the semiconductor device 1 allows the first ferroelectric capacitor 14 and the second ferroelectric capacitor 24 to store the states of the first storage node N1 and the second storage node N2. Specifically, a predetermined operation allows the semiconductor device 1 to control the polarized states of the ferroelectric films of the first ferroelectric capacitor 14 and second ferroelectric capacitor 24 on the basis of the electric potentials of the first storage node N1 and second storage node N2.

This allows the semiconductor device 1 to operate as a flip-flop circuit at the time of power supply and it is thus possible to write or read information at high speed. In addition, the semiconductor device 1 is able to store the information retained in the flip-flop circuit in the non-volatile first ferroelectric capacitor 14 and second ferroelectric capacitor 24 when supplied with no power.

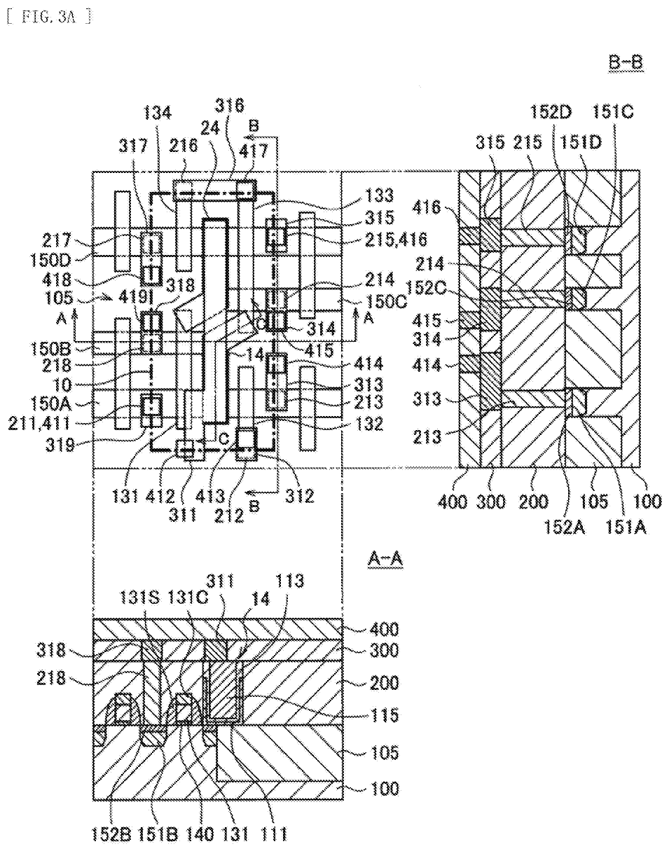

Next, with reference to FIG. 2, a case is described where the semiconductor device 1 illustrated in FIG. 1 is applied to a memory cell of a storage apparatus. FIG. 2 is a circuit diagram illustrating an equivalent circuit of a memory cell of a storage apparatus to which the semiconductor device 1 illustrated in FIG. 1 is applied.

As illustrated in FIG. 2, a memory cell 10 of a storage apparatus further includes first selection FET 15 and second selection FET 25 in addition to each component of the semiconductor device 1 illustrated in FIG. 1.

The first selection FET 15 and the second selection FET 25 are field effect transistors that control whether or not the memory cell 10 is selected. The first selection FET 15 and the second selection FET 25 are formed as n-type FETs.

One of the source or drain of the first selection FET 15 is electrically coupled to the other of the electrodes of the first ferroelectric capacitor 14. The other of the source or drain of the first selection FET 15 is electrically coupled to a first bit line BL1. The gate of the first selection FET 15 is electrically coupled to a word line WL. The on/off state of the channel of the first selection FET 15 is controlled in accordance with a voltage applied from the word line WL.

One of the source or drain of the second selection FET 25 is electrically coupled to the other of the electrodes of the second ferroelectric capacitor 24. The other of the source or drain of the second selection FET 25 is electrically coupled to a second bit line BL2. The gate of the second selection FET 25 is electrically coupled to a word line WL. The on/off state of the channel of the second selection FET 25 is controlled in accordance with a voltage applied from the word line WL.

In a case where information is written in the memory cell 10 of the storage apparatus, a high electric potential is first set as the electric potential of the word line WL to cause the channels of the first selection FET 15 and second selection FET 25 to each transition to an on state. Next, applying symmetric electric potentials (one of which is a high electric potential and the other of which is a low electric potential) to the first bit line BL1 and the second bit line BL2 allows the state of the flip-flop of the semiconductor device 1 to be controlled. Afterward, a low electric potential is set as the electric potential of the word line WL to cause the channels of the first selection FET 15 and second selection FET 25 to each transition to an off state. This allows the memory cell 10 of the storage apparatus to write information in the flip-flop circuit of the semiconductor device 1.

In contrast, in a case where information is read from the memory cell 10 of the storage apparatus, the electric potential of the word line WL is first turned off and the same electric potentials are then applied to the first bit line BL1 and the second bit line BL2. Next, a high electric potential is set as the electric potential of the word line WL. At this time, it is changed on the basis of the state of the flip-flop of the semiconductor device 1 which of the first bit line BL1 and the second bit line BL2 has a high electric potential and which of them has a low electric potential. The memory cell 10 of the storage apparatus is thus able to read information from the flip-flop circuit of the semiconductor device 1 by amplifying the electric potential of the first bit line BL1 and the electric potential of the second bit line BL2 with an amplifier or the like.

This allows the storage apparatus including the memory cell 10 to operate as a storage apparatus that performs an operation similar to that of SRAM. It is to be noted that an operation of storing the information written in the flip-flop circuit of the semiconductor device 1 in the first ferroelectric capacitor 14 and the second ferroelectric capacitor 24 and an operation of restoring the information stored in the first ferroelectric capacitor 14 and the second ferroelectric capacitor 24 to the flip-flop circuit of the semiconductor device 1 in the storage apparatus including the memory cell 10 are described below.

The semiconductor device 1 according to the present embodiment is therefore able to write or read information at high speed as with SRAM and retain information in the first ferroelectric capacitor 14 and the second ferroelectric capacitor 24 even with no power supply.

### 2. Structure Example

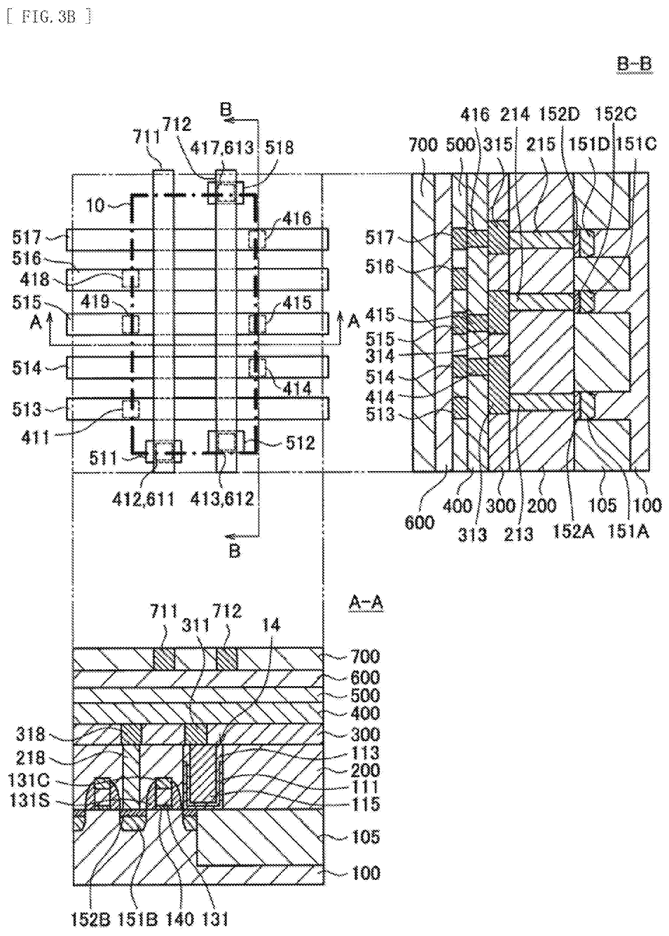

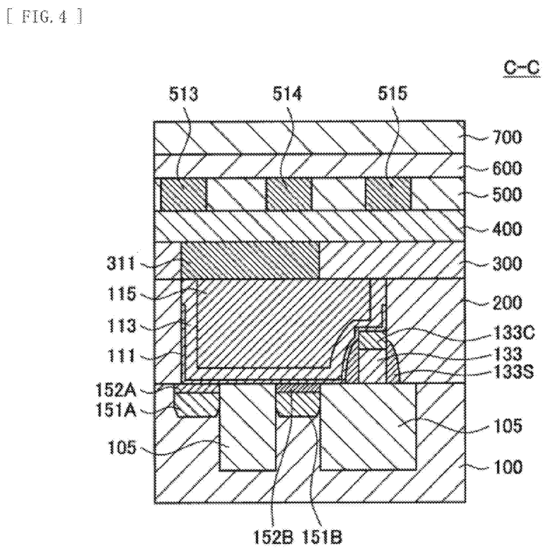

Next, with reference to FIGS. 3A, 3B, and 4, the specific structure is described of a storage apparatus in which the semiconductor device 1 according to the present embodiment is included in a memory cell. FIGS. 3A and 3B are schematic diagrams each illustrating the planar structure and cross-sectional structure of the memory cell 10 including the semiconductor device 1. The cross-sectional views of FIGS. 3A and 3B respectively illustrate cross sections obtained by cutting the plan views of FIGS. 3A and 3B along A-A lines or B-B lines. FIG. 4 is a schematic diagram illustrating cross sections obtain by cutting the plan views of FIGS. 3A and 3B along the C-C lines.

It is to be noted that the plan views of FIGS. 3A and 3B omit layers formed over the entire surface of a semiconductor substrate 100 to clarify the disposition of respective components. In addition, the plan view and cross-sectional views of FIG. 3A illustrate only the components of the layers below a second interlayer insulating film 400. The plan view of FIG. 3B illustrates only the components of the layers above a third interlayer insulating film 500.

As illustrated in FIGS. 3A and 3B, the memory cell 10 including the semiconductor device 1 is provided above the semiconductor substrate 100. A large number of the memory cells 10 are disposed above the semiconductor substrate 100 in a matrix, thereby configuring a storage apparatus that is able to store a huge mass of information.

The first inverting circuit 11 includes the p-type FET 12 and the n-type FET 13. The p-type FET 12 is formed by providing a gate electrode 131 above an n-type activation region 150B with a gate insulating film 140 interposed therebetween. The n-type FET 13 is formed by providing the gate electrode 131 above a p-type activation region 150A with the gate insulating film 140 interposed therebetween.

The one of the source or drain of the p-type FET 12 is electrically coupled to a second wiring layer 515 via a first contact 218, a first wiring layer 318, and a second contact 419. The second wiring layer 515 functions as the power supply line PWR. The other of the source or drain of the p-type FET 12 is electrically coupled to the one of the source or drain of the n-type FET 13 via a lower electrode 111 of the first ferroelectric capacitor 14. The n-type FET 13 is provided to the p-type activation region 150A. The other of the source or drain of the n-type FET 13 is electrically coupled to a second wiring layer 513 via a first contact 211, a first wiring layer 319, and a second contact 411. The second wiring layer 513 functions as the ground line GND.

The first ferroelectric capacitor 14 is provided in a shared contact provided over a gate electrode 133, the n-type activation region 150B, and the p-type activation region 150A. Specifically, the first ferroelectric capacitor 14 includes the lower electrode 111, a ferroelectric film 113, and an upper electrode 115. The lower electrode 111 is provided along the inside of an opening that penetrates a planarization film 200. The ferroelectric film 113 is provided on the lower electrode 111 along the opening. The upper electrode 115 is provided on the ferroelectric film 113 to fill the opening.

The lower electrode 111 of the first ferroelectric capacitor 14 is electrically coupled to the gate electrode 133, the other of the source or drain of the p-type FET 12 provided to the n-type activation region 150B, and the one of the source or drain of the n-type FET 13 provided to the p-type activation region 150A. The upper electrode 115 of the first ferroelectric capacitor 14 is electrically coupled to a third wiring layer 711 via a first wiring layer 311, a second contact 412, a second wiring layer 511, and a third contact 611. The third wiring layer 711 functions as the plate line PL.

The first selection FET 15 is formed as n-type FET by providing a gate electrode 132 above the p-type activation region 150A with the gate insulating film 140 interposed therebetween. The one of the source or drain of the first selection FET 15 is electrically coupled to the lower electrode 111 of the first ferroelectric capacitor 14. The other of the source or drain of the first selection FET 15 is electrically coupled to a second wiring layer 514 via a first contact 213, a first wiring layer 313, and a second contact 414. The second wiring layer 514 functions as the first bit line BL1. The gate electrode 132 of the first selection FET 15 is electrically coupled to a third wiring layer 712 via a first contact 212, a first wiring layer 312, a second contact 413, a second wiring layer 512, and a third contact 612. The third wiring layer 712 functions as the word line WL.

The second inverting circuit 21 includes the p-type FET 22 and the n-type FET 23. The p-type FET 22 is formed by providing the gate electrode 133 above an n-type activation region 150C with the gate insulating film 140 interposed therebetween. The n-type FET 23 is formed by providing the gate electrode 133 above a p-type activation region 150D with the gate insulating film 140 interposed therebetween.

The one of the source or drain of the p-type FET 22 is electrically coupled to the second wiring layer 515 via a first contact 214, a first wiring layer 314, and a second contact 415. The second wiring layer 515 functions as the power supply line PWR. The other of the source or drain of the p-type FET 22 is electrically coupled to the one of the source or drain of the n-type FET 23 via the lower electrode 111 of the second ferroelectric capacitor 24. The n-type FET 23 is provided to the p-type activation region 150D. The other of the source or drain of the n-type FET 23 is electrically coupled to a second wiring layer 517 via a first contact 215, a first wiring layer 315, and a second contact 416. The second wiring layer 517 functions as the ground line GND.

The second ferroelectric capacitor 24 is provided in a shared contact provided over the gate electrode 131, the n-type activation region 150C, and the p-type activation region 150D. Specifically, although not illustrated, as with the first ferroelectric capacitor 14, the second ferroelectric capacitor 24 includes a lower electrode, a ferroelectric film, and an upper electrode. The lower electrode is provided along the inside of an opening that penetrates the planarization film 200. The ferroelectric film is provided on the lower electrode along the opening. The upper electrode is provided on the ferroelectric film to fill the opening.

The lower electrode of the second ferroelectric capacitor 24 is electrically coupled to the gate electrode 131, the other of the source or drain of the p-type FET 22 provided to the n-type activation region 150C, and the one of the source or drain of the n-type FET 23 provided to the p-type activation region 150D. The upper electrode of the second ferroelectric capacitor 24 is electrically coupled to the third wiring layer 711 via the first wiring layer 311, the second contact 412, the second wiring layer 511, and the third contact 611. The third wiring layer 711 functions as the plate line PL.

The second selection FET 25 is formed as n-type FET by providing a gate electrode 134 above the p-type activation region 150D with the gate insulating film 140 interposed therebetween. The one of the source or drain of the second selection FET 25 is electrically coupled to the lower electrode of the second ferroelectric capacitor 24. The other of the source or drain of the second selection FET 25 is electrically coupled to a second wiring layer 516 via a first contact 217, a first wiring layer 317, and a second contact 418. The second wiring layer 516 functions as the second bit line BL2. The gate electrode 134 of the second selection FET 25 is electrically coupled to the third wiring layer 712 via a first contact 216, a first wiring layer 316, a second contact 417, a second wiring layer 518, and a third contact 613. The third wiring layer 712 functions as the word line WL.

The following more specifically describes each component of the memory cell 10.

The semiconductor substrate 100 is a substrate that includes a semiconductor material and has each FET formed thereon. The semiconductor substrate 100 may be a silicon substrate or may be an SOI (Silicon On Insulator) substrate having an insulating film such as SiO₂ inserted into a silicon substrate. Alternatively, the semiconductor substrate 100 may be a substrate including another elemental semiconductor such as germanium or a substrate including a compound semiconductor such as gallium arsenide (GaAs), gallium nitride (GaN), or silicon carbide (SiC).

An element isolation layer 105 includes an insulating material and electrically insulates activation regions provided on the semiconductor substrate 100 from each other. Specifically, the element isolation layer 105 is provided to separate the p-type activation regions 150A and 150D and the n-type activation regions 150B and 150C from each other. The p-type activation regions 150A and 150D and the n-type activation regions 150B and 150C are each provided as a band-shaped region that extends in a first direction (e.g., left-right direction when facing FIG. 2) and each function as an activation region in which each FET is formed.

For example, the p-type activation regions 150A and 150D may be each formed by introducing a p-type impurity such as boron (B) or aluminum (Al) to the semiconductor substrate 100. The n-type activation regions 150B and 150C may be each formed by introducing an n-type impurity such as phosphorus (P) or arsenic (As) to the semiconductor substrate 100.

The element isolation layer 105 may include an insulating oxynitride such as silicon oxide (SiOₓ), silicon nitride (SiNₓ), or silicon oxynitride (SiON). Specifically, the element isolation layer 105 may be formed by removing a portion of a predetermined region of the semiconductor substrate 100 by etching or the like and then filling a formed opening with silicon oxide (SiOₓ) by using STI (Shallow Trench Isolation). In addition, the element isolation layer 105 may be formed by thermally oxidizing a predetermined region of the semiconductor substrate 100 by using LOCOS (Local Oxidation of Silicon).

The gate insulating film 140 includes an insulating material and is provided on each of the p-type activation regions 150A and 150D and n-type activation regions 150B and 150C of the semiconductor substrate 100. The gate insulating film 140 may include an insulating material known as a gate insulating film of a field effect transistor. For example, the gate insulating film 140 may include an insulating oxynitride such as silicon oxide (SiOₓ), silicon nitride (SiNₓ), or silicon oxynitride (SiON).

The gate electrodes 131, 132, 133, and 134 each include an electrically conductive material and are provided on the gate insulating film 140. The gate electrodes 131, 132, 133, and 134 are provided by being extended in a second direction orthogonal to the first direction in which the p-type activation regions 150A and 150D and the n-type activation regions 150B and 150C extend. Specifically, the gate electrode 131 is provided across the n-type activation region 150B and the p-type activation region 150A to form the p-type FET 12 and the n-type FET 13. The gate electrode 132 is provided across the p-type activation region 150A to form the first selection FET 15 that is n-type FET. The gate electrode 133 is provided across the n-type activation region 150C and the p-type activation region 150D to form the p-type FET 22 and the n-type FET 23. The gate electrode 134 is provided across the p-type activation region 150D to form the second selection FET 25 that is n-type FET.

For example, the gate electrodes 131, 132, 133, and 134 may each include polysilicon or the like. The gate electrodes 131, 132, 133, and 134 may each include metal, alloy, a metal compound, or an alloy (so-called silicide) of metal (such as Ni) and polysilicon. Specifically, the gate electrodes 131, 132, 133, and 134 may be each formed to have a structure in which a metal layer and a polysilicon layer are stacked. For example, the gate electrodes 131, 132, 133, and 134 may be each formed to have a structure in which a metal layer including TiN or TaN provided on the gate insulating film 140 and a polysilicon layer are stacked.

Source or drain regions 151A and 151D are n-type regions that are formed in the respective p-type activation regions 150A and 150D. The source or drain regions 151A and 151D may be formed by introducing n-type impurities such as phosphorus (P) or arsenic (As) to the p-type activation regions 150A and 150D in the semiconductor substrate 100. It is to be noted that the semiconductor substrate 100 between the source or drain regions 151A and 151D and the gate electrodes 131, 132, 133, and 134 may have LDD (Lightly-Doped Drain) regions. Each LDD region is an n-type region as with the source or drain regions 151A and 151D and has a lower concentration of electrically conductive impurities than that of each of the source or drain regions 151A and 151D.

Specifically, the respective source or drain regions 151A are provided to the p-type activation region 150A to sandwich the gate electrodes 131 and 132. The source or drain region 151A provided on the side opposed to the gate electrode 132 with the gate electrode 131 interposed therebetween is electrically coupled to the second wiring layer 513 via the first contact 211, the first wiring layer 319, and the second contact 411. The second wiring layer 513 functions as the ground line GND. The source or drain region 151A provided on the side opposed to the gate electrode 131 with the gate electrode 132 interposed therebetween is electrically coupled to the second wiring layer 514 via the first contact 213, the first wiring layer 313, and the second contact 414. The second wiring layer 514 functions as the first bit line BL1.

The respective source or drain regions 151D are provided to the p-type activation region 150D to sandwich the gate electrodes 133 and 134. The source or drain region 151D provided on the side opposed to the gate electrode 134 with the gate electrode 133 interposed therebetween is electrically coupled to the second wiring layer 517 via the first contact 215, the first wiring layer 315, and the second contact 416. The second wiring layer 517 functions as the ground line GND. The source or drain region 151D provided on the side opposed to the gate electrode 133 with the gate electrode 134 interposed therebetween is electrically coupled to the second wiring layer 516 via the first contact 217, the first wiring layer 317, and the second contact 418. The second wiring layer 516 functions as the second bit line BL2.

Source or drain regions 151B and 151C are p-type regions that are formed in the respective n-type activation regions 150B and 150C. The source or drain regions 151B and 151C may be formed by introducing p-type impurities such as boron (B) or aluminum (Al) to the n-type activation regions 150B and 150C in the semiconductor substrate 100. It is to be noted that the semiconductor substrate 100 between the source or drain regions 151B and 151C and the gate electrodes 131 and 133 may have LDD (Lightly-Doped Drain) regions. Each LDD region is an p-type region as with the source or drain regions 151B and 151C and has a lower concentration of electrically conductive impurities than that of each of the source or drain regions 151B and 151C.

Specifically, the respective source or drain regions 151B are provided to the n-type activation region 150B to sandwich the gate electrode 131. One of the source or drain regions 151B is electrically coupled to the lower electrode 111 of the first ferroelectric capacitor 14. The source or drain region 151B provided on the side opposed to the first ferroelectric capacitor 14 with the gate electrode 131 interposed therebetween is electrically coupled to the second wiring layer 515 via the first contact 218, the first wiring layer 318, and the second contact 419. The second wiring layer 515 functions as the power supply line PWR.

The respective source or drain regions 151C are provided to the n-type activation region 150C to sandwich the gate electrode 133. One of the source or drain regions 151C is electrically coupled to the lower electrode of the second ferroelectric capacitor 24. The source or drain region 151C provided on the side opposed to the second ferroelectric capacitor 24 with the gate electrode 133 interposed therebetween is electrically coupled to the second wiring layer 515 via the first contact 214, the first wiring layer 314, and the second contact 415. The second wiring layer 515 functions as the power supply line PWR.

Sidewall insulating films 1315, 132S, 133S, and 134S (the sidewall insulating films 132S, 133S, and 134S are not, however, illustrated) include insulating materials and provided to the side surfaces of the respective gate electrodes 131, 132, 133, and 134 as sidewalls. Specifically, it is possible to form each of the sidewall insulating films 1315, 132S, 133S, and 134S by uniformly forming an insulating film on a region including the gate electrodes 131, 132, 133, and 134 and then performing vertical anisotropic etching on the insulating film. For example, the sidewall insulating films 1315, 132S, 133S, and 134S may be each formed as a single layer or multiple layers of an insulating oxynitride such as silicon oxide (SiOₓ), silicon nitride (SiNₓ), or silicon oxynitride (SiON).

The sidewall insulating films 1315, 132S, 133S, and 134S each block an n-type impurity or a p-type impurity when the n-type impurity or the p-type impurity is introduced to the semiconductor substrate 100. This allows the sidewall insulating films 1315, 132S, 133S, and 134S to control the positional relationships between the gate electrodes 131, 132, 133, and 134 and the source or drain regions 151A, 151B, 151C, and 151D in a self-aligning manner. The sidewall insulating films 1315, 132S, 133S, and 134S are each able to control the introduction of an n-type impurity or p-type impurity to the semiconductor substrate 100 step by step. This makes it possible to form the above-described LDD regions between the source or drain regions 151A, 151B, 151C, and 151D and the gate electrodes 131, 132, 133, and 134 in a self-alignment manner.

Conductive layers 131C, 132C, 133C, and 134C (the conductive layers 132C, 133C, and 134C are not, however, illustrated) are respectively provided on the gate electrodes 131, 132, 133, and 134 to increase the electrical conductivity of the gate electrodes 131, 132, 133, and 134. For example, the conductive layers 131C, 132C, 133C, and 134C may each include metal or a metal compound.

Contact regions 152A, 152B, 152C, and 152D are respectively provided to the source or drain regions 151A, 151B, 151C, and 151D of the surface of the semiconductor substrate 100. The contact regions 152A, 152B, 152C, and 152D lower the contact resistance between the source or drain regions 151A, 151B, 151C, and 151D, the first contacts 211, 213, 214, 215, 217, and 218, and the lower electrodes of the first ferroelectric capacitor 14 and second ferroelectric capacitor 24. Specifically, the contact regions 152A, 152B, 152C, and 152D may each include an alloy (so-called silicide) of metal such as Ni and silicon.

The planarization film 200 includes an insulating material. Each FET is embedded in the planarization film 200. The planarization film 200 is provided over the entire surface of the semiconductor substrate 100. For example, the planarization film 200 may include an insulating oxynitride such as silicon oxide (SiOₓ), silicon nitride (SiNₓ), or silicon oxynitride (SiON).

The planarization film 200 is provided with openings for exposing the gate electrode 133, the source or drain region 151B, and the source or drain region 151A between the gate electrodes 131 and 132 and openings for exposing the gate electrode 131, the source or drain region 151C, and the source or drain region 151D between the gate electrodes 133 and 134. In addition, the planarization film 200 is provided with openings for exposing the first contacts 211, 212, 213, 214, 215, 216, 217, and 218. The inside of each of the openings for exposing the gate electrode 133, the source or drain region 151B, and the source or drain region 151A between the gate electrodes 131 and 132 is provided with the first ferroelectric capacitor 14. The inside of each of the openings for exposing the gate electrode 131, the source or drain region 151C, and the source or drain region 151D between the gate electrodes 133 and 134 is provided with the second ferroelectric capacitor 24.

It is to be noted that, although not illustrated in FIGS. 3A, 3B, and 4, a linear layer including an insulating material may be provided over the entire surface of the semiconductor substrate 100 above the semiconductor substrate 100, the sidewall insulating films 1315, 132S, 133S, and 134S, and the conductive layers 131C, 132C, 133C, and 134C. The linear layer makes it possible to provide high etching selectivity between the linear layer and the planarization film 200 in the step of forming the above-described openings in the planarization film 200. This allows the linear layer to prevent etching from proceeding in the semiconductor substrate 100 in the step. For example, the linear layer may include an insulating oxynitride such as silicon oxide (SiOₓ), silicon nitride (SiNₓ), or silicon oxynitride (SiON). Specifically, in a case where the planarization film 200 includes silicon oxide (SiOₓ), the liner layer may include silicon nitride (SiNₓ).

In addition, the liner layer may be formed as a layer that applies compression stress or tensile stress to the semiconductor substrate 100 below the gate insulating film 140. In such a case, the liner layer makes it possible to increase the carrier mobility of a channel formed in the semiconductor substrate 100 by the stress effects.

Here, the components of the first ferroelectric capacitor 14 are described further with reference to FIG. 4.

As illustrated in FIG. 4, the first ferroelectric capacitor 14 is a capacitor in the shape of a stacked cylinder and includes the lower electrode 111, the ferroelectric film 113, and the upper electrode 115.

The lower electrode 111 includes an electrically conductive material and is provided along the inside of each of the openings formed in the planarization film 200 to expose the source or drain regions 151A and 151B and the gate electrode 133. Specifically, the openings formed in the planarization film 200 are provided to have bent planar shapes to expose the gate electrode 133, the source or drain region 151B, and the source or drain region 151A between the gate electrodes 131 and 132. This allows the lower electrodes 111 to electrically couple the source or drain regions 151A and 151B and gate electrode 133 exposed by the openings to each other.

For example, the lower electrode 111 may include metal such as titanium (Ti) or tungsten (W) or a metal compound such as titanium nitride (TiN) or tantalum nitride (TaN). In addition, the lower electrode 111 may include ruthenium (Ru), ruthenium oxide (RuO₂), or the like. It is possible to form the lower electrode 111 by using sputtering such as ALD (Atomic Layer Deposition), CVD (Chemical Vapor Deposition), or IMP (Ionized Metal Plasma).

The ferroelectric film 113 includes a ferroelectric material and is provided on the lower electrode 111 along the inside of an opening formed in the planarization film 200. The ferroelectric film 113 includes a ferroelectric material that spontaneously polarizes and is able to control the direction of remanent polarization by an external electric field. For example, the ferroelectric film 113 may include a ferroelectric material such as lead zirconate titanate (Pb(Zr,Ti)O₃: PZT) or strontium bismuth tantalate (SrBi₂Ta₂O₉: SBT) having a perebskite structure. In addition, the ferroelectric film 113 may be a ferroelectric film in which a film including a high dielectric material such as HfOₓ, ZrOₓ, or HfZrOₓ is altered by heat treatment or the like. The ferroelectric film 113 may be a ferroelectric film that is altered by introducing atoms such as lanthanum (La), silicon (Si), or gadolinium (Gd) to the above-described film including a high dielectric material. Further, the ferroelectric film 113 may be formed as a single layer or multiple layers. For example, the ferroelectric film 113 may be a single-layer film including a ferroelectric material such as HfOₓ. It is possible to form the ferroelectric film 113 by using ALD, CVD, or the like.

The upper electrode 115 includes an electrically conductive material and is provided on the ferroelectric film 113 to fill an opening formed in the planarization film 200. For example, the upper electrode 115 may include metal such as titanium (Ti) or tungsten (W) or a metal compound such as titanium nitride (TiN) or tantalum nitride (TaN). In addition, the upper electrode 115 may include ruthenium (Ru), ruthenium oxide (RuO₂), or the like. It is possible to form the upper electrode 115 by using ALD, CVD, or the like.

It is to be noted that the lower electrode, ferroelectric film, and upper electrode included in the second ferroelectric capacitor 24 are substantially similar to those of the first ferroelectric capacitor except for planar positions for formation and are not thus described here.

The first contacts 211, 212, 213, 214, 215, 216, 217, and 218 each include an electrically conductive material and are provided through the planarization film 200. For example, the first contacts 211, 212, 213, 214, 215, 216, 217, and 218 may each include metal such as titanium (Ti) or tungsten (W) having low resistance or a metal compound such as titanium nitride (TiN) or tantalum nitride (TaN). The first contacts 211, 212, 213, 214, 215, 216, 217, and 218 may be each formed as a single layer or a stack of multiple layers. For example, the first contacts 211, 212, 213, 214, 215, 216, 217, and 218 may be each formed as a stack of Ti or TiN and W.

Specifically, the first contact 211 is provided on the source or drain region 151A provided on the side opposed to the gate electrode 132 with the gate electrode 131 interposed therebetween. The first contact 211 electrically couples the other of the source or drain of the n-type FET 13 and the first wiring layer 319. The first contact 212 is provided on the gate electrode 132 and electrically couples the gate electrode 132 of the first selection FET 15 and the first wiring layer 312. The first contact 213 is provided on the source or drain region 151A provided on the side opposed to the gate electrode 131 with the gate electrode 132 interposed therebetween. The first contact 213 electrically couples the other of the source or drain of the first selection FET 15 and the first wiring layer 313. The first contact 214 is provided on the source or drain region 151C provided on the side opposed to the second ferroelectric capacitor 24 with the gate electrode 133 interposed therebetween. The first contact 214 electrically couples the one of the source or drain of the p-type FET 22 and the first wiring layer 314.

The first contact 215 is provided on the source or drain region 151D provided on the side opposed to the gate electrode 134 with the gate electrode 133 interposed therebetween. The first contact 215 electrically couples the other of the source or drain of the n-type FET 23 and the first wiring layer 315. The first contact 216 is provided on the gate electrode 134 and electrically couples the gate electrode 134 of the second selection FET 25 and the first wiring layer 316. The first contact 217 is provided on the source or drain region 151D provided on the side opposed to the gate electrode 133 with the gate electrode 134 interposed therebetween. The first contact 217 electrically couples the other of the source or drain of the second selection FET 25 and the first wiring layer 317. The first contact 218 is provided on the source or drain region 151B provided on the side opposed to the first ferroelectric capacitor 14 with the gate electrode 131 interposed therebetween. The first contact 218 electrically couples the one of the source or drain of the p-type FET 12 and the first wiring layer 318.

The first wiring layers 311, 312, 313, 314, 315, 316, 317, 318, and 319 are embedded in a first interlayer insulating film 300. The first interlayer insulating film 300 is provided on the planarization film 200 over the entire surface of the semiconductor substrate 100. The first interlayer insulating film 300 may include, for example, an insulating oxynitride such as silicon oxide (SiOₓ), silicon nitride (SiNₓ), or silicon oxynitride (SiON).

The first wiring layers 311, 312, 313, 314, 315, 316, 317, 318, and 319 each include an electrically conductive material and are provided on the planarization film 200. The first wiring layers 311, 312, 313, 314, 315, 316, 317, 318, and 319 may each include, for example, a metal material such as copper (Cu) or aluminum (Al) or may be each formed to have a damascene structure or a dual damascene structure for Cu.

Specifically, the first wiring layer 311 is provided on the first ferroelectric capacitor 14 and the second ferroelectric capacitor 24 and electrically couples the upper electrodes of the first ferroelectric capacitor 14 and second ferroelectric capacitor 24 to each other. The first wiring layer 312 is provided on the first contact 212. The first wiring layer 313 is provided on the first contact 213. The first wiring layer 314 is provided on the first contact 214. The first wiring layer 315 is provided on the first contact 215. The first wiring layer 316 is provided on the first contact 216. The first wiring layer 317 is provided on the first contact 217. The first wiring layer 318 is provided on the first contact 218. The first wiring layer 319 is provided on the first contact 211.

The second contacts 411, 412, 413, 414, 415, 416, 417, 418, and 419 are embedded in a second interlayer insulating film 400. The second interlayer insulating film 400 is provided on the first interlayer insulating film 300 over the entire surface of the semiconductor substrate 100. The second interlayer insulating film 400 may include, for example, an insulating oxynitride such as silicon oxide (SiOₓ), silicon nitride (SiNₓ), or silicon oxynitride (SiON).

The second contacts 411, 412, 413, 414, 415, 416, 417, and 418 each include an electrically conductive material and are provided through the second interlayer insulating film 400. For example, the second contacts 411, 412, 413, 414, 415, 416, 417, and 418 may each include metal such as titanium (Ti) or tungsten (W) having low resistance or a metal compound such as titanium nitride (TiN) or tantalum nitride (TaN). The second contacts 411, 412, 413, 414, 415, 416, 417, and 418 may be each formed as a single layer or a stack of multiple layers. For example, the second contacts 411, 412, 413, 414, 415, 416, 417, and 418 may be each formed as a stack of Ti or TiN and W.

Specifically, the second contact 411 is provided on the first wiring layer 319. The second contact 412 is provided on the first wiring layer 311. The second contact 413 is provided on the first wiring layer 312. The second contact 414 is provided on the first wiring layer 313. The second contact 415 is provided on the first wiring layer 314. The second contact 416 is provided on the first wiring layer 315. The second contact 417 is provided on the first wiring layer 316. The second contact 418 is provided on the first wiring layer 317. The second contact 419 is provided on the first wiring layer 318.

The wiring layers 511, 512, 513, 514, 515, 516, 517, and 518 are embedded in the third interlayer insulating film 500. The third interlayer insulating film 500 is provided on the second interlayer insulating film 400 over the entire surface of the semiconductor substrate 100. The third interlayer insulating film 500 may include, for example, an insulating oxynitride such as silicon oxide (SiOₓ), silicon nitride (SiNₓ), or silicon oxynitride (SiON).

The second wiring layers 511, 512, 513, 514, 515, 516, 517, and 518 each include an electrically conductive material and are provided on the second interlayer insulating film 400. The second wiring layers 511, 512, 513, 514, 515, 516, 517, and 518 may each include, for example, a metal material such as copper (Cu) or aluminum (Al) or may be each formed to have a damascene structure or a dual damascene structure for Cu.

Specifically, the second wiring layer 513 is provided on the second contact 411 as the ground line GND that extends in the first direction. The second wiring layer 514 is provided on the second contact 414 as the first bit line BL1 that extends in the first direction. The second wiring layer 515 is provided on the second contacts 415 and 419 as the power supply line PWR that extends in the first direction. The second wiring layer 516 is provided on the second contact 418 as the second bit line BL2 that extends in the first direction. The second wiring layer 517 is provided on the second contact 416 as the ground line GND that extends in the first direction. The second wiring layer 511 is provided on the second contact 412. The second wiring layer 512 is provided on the second contact 413. The second wiring layer 518 is provided on the second contact 417.

The third contacts 611, 612, and 613 are embedded in a fourth interlayer insulating film 600. The fourth interlayer insulating film 600 is provided on the third interlayer insulating film 500 over the entire surface of the semiconductor substrate 100. The fourth interlayer insulating film 600 may include, for example, an insulating oxynitride such as silicon oxide (SiOₓ), silicon nitride (SiNₓ), or silicon oxynitride (SiON).

The third contacts 611, 612, and 613 each include an electrically conductive material and are provided through the fourth interlayer insulating film 600. For example, the third contacts 611, 612, and 613 may each include metal such as titanium (Ti) or tungsten (W) having low resistance or a metal compound such as titanium nitride (TiN) or tantalum nitride (TaN). The third contacts 611, 612, and 613 may be each formed as a single layer or a stack of multiple layers. For example, the third contacts 611, 612, and 613 may be each formed as a stack of Ti or TiN and W.

Specifically, the third contact 611 is provided on the second wiring layer 511. The third contact 612 is provided on the second wiring layer 512. The third contact 613 is provided on the second wiring layer 518.

The third wiring layers 711 and 712 are embedded in a fifth interlayer insulating film 700. The fifth interlayer insulating film 700 is provided on the fourth interlayer insulating film 600 over the entire surface of the semiconductor substrate 100. The fifth interlayer insulating film 700 may include, for example, an insulating oxynitride such as silicon oxide (SiOₓ), silicon nitride (SiNₓ), or silicon oxynitride (SiON).

The third wiring layers 711 and 712 each include an electrically conductive material and are provided on the fourth interlayer insulating film 600. The third wiring layers 711 and 712 may each include, for example, a metal material such as copper (Cu) or aluminum (Al) or may be each formed to have a damascene structure or a dual damascene structure for Cu. Specifically, the third wiring layer 711 is provided on the third contact 611 as the plate line PL that extends in the second direction orthogonal to the first direction. The third wiring layer 712 is provided on the third contacts 612 and 613 as the word line WL that extends in the second direction orthogonal to the first direction.

The above-described structure allows the memory cell 10 including the semiconductor device 1 to have the first ferroelectric capacitor 14 and the second ferroelectric capacitor 24 formed in the shared contacts in the shape of a stacked cylinder. This allows the memory cell 10 to further reduce the planar area, facilitating the storage apparatus to have higher storage density. In addition, the memory cell 10 allows the first ferroelectric capacitor 14 and the second ferroelectric capacitor 24 to each have larger capacity, making it possible to increase the reliability of the memory cell 10.

### 3. Manufacturing Method

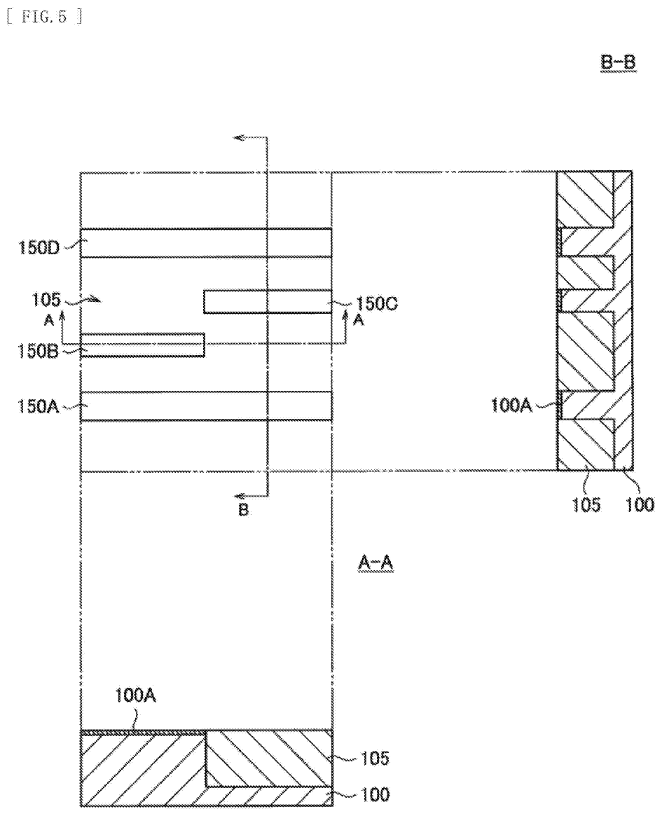

Next, a method of manufacturing the memory cell 10 including the semiconductor device 1 according to the present embodiment is described with reference to FIGS. 5 to 15. FIGS. 5 to 15 are plan views and cross-sectional views describing the respective steps of the method of manufacturing the memory cell 10.

It is to be noted that FIGS. 5 to 15 also omit the description of the layers formed over the entire surface of the semiconductor substrate 100 as with FIGS. 3A and 3B. In addition, the respective cross-sectional views illustrate cross sections obtained by cutting the plan views along the A-A lines or the B-B lines.

As illustrated in FIG. 5, the element isolation layer 105 is first formed on the semiconductor substrate 100 to form the p-type activation regions 150A and 150D and n-type activation regions 150B and 150C in which the respective FETs are formed.

Specifically, a SiO₂ film is formed on the semiconductor substrate 100 including Si by dry oxidization or the like. A Si₃N₄ film is further formed by low-pressure CVD (Chemical Vapor Deposition) or the like. Next, a resist layer patterned to protect the regions for forming the p-type activation regions 150A and 150D and n-type activation regions 150B and 150C is formed on the Si₃N₄ film and the SiO₂ film, the Si₃N₄ film, and the semiconductor substrate 100 are then etched to each have a depth of 350 nm to 400 nm. Next, a film of SiO₂ is formed to have a film thickness of 650 nm to 700 nm and an opening formed by etching is filled, thereby forming the element isolation layer 105. For example, high-density plasma CVD may be used to form a film of SiO₂. This high-density plasma CVD is favorable to cover a step and allows a dense SiO₂ film.

Subsequently, the excessively formed SiO₂ film is removed by using CMP (Chemical Mechanical Polish) or the like, thereby planarizing the surface of the semiconductor substrate 100. It is sufficient if the SiO₂ film is removed by CMP, for example, until the Si₃N₄ film is exposed.

Further, hot phosphoric acid or the like is used to remove the Si₃N₄ film. It is to be noted that it is also possible to anneal the semiconductor substrate 100 in an N₂, O₂ or H₂/O₂ environment before removing the Si₃N₄ film to make the SiO₂ film of the element isolation layer 105 more dense or round the corners of the p-type activation regions 150A and 150D and the n-type activation regions 150B and 150C.

Next, the surface of each of the regions of the semiconductor substrate 100 corresponding to the p-type activation regions 150A and 150D and n-type activation regions 150B and 150C is oxidized by about 10 nm to form an oxide film 100A. Afterward, p-type impurities (e.g., boron (B) or the like) are ion-implanted to the regions of the semiconductor substrate 100 corresponding to the p-type activation regions 150A and 150D, thereby forming the p-type activation regions 150A and 150D. In addition, n-type impurities (e.g., arsenic (As) or the like) are ion-implanted to the regions of the semiconductor substrate 100 corresponding to the n-type activation regions 150B and 150C, thereby forming the n-type activation regions 150B and 150C.

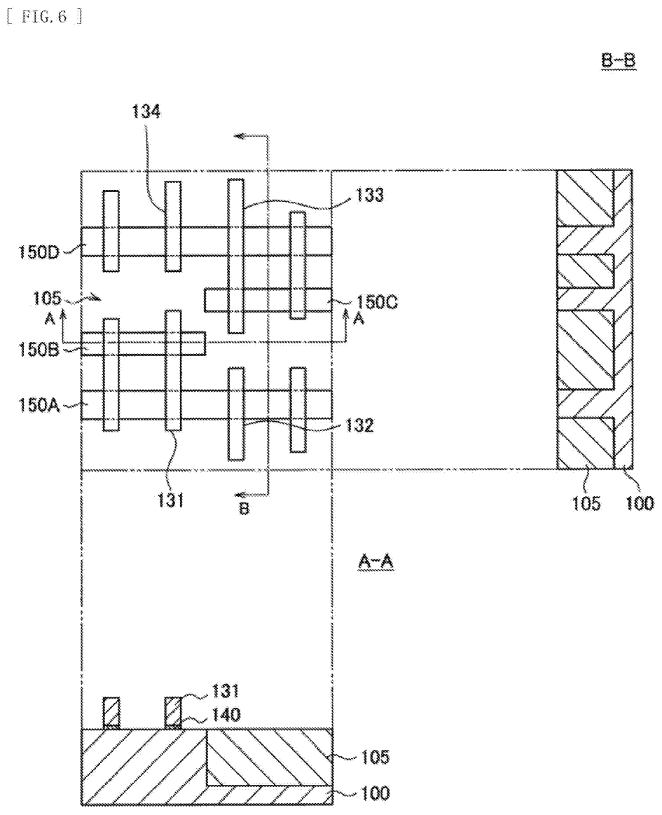

Next, as illustrated in FIG. 6, after the gate insulating film 140 is formed, the gate electrodes 131, 132, 133, and 134 are formed on the gate insulating film 140.

Specifically, the oxide film 100A that covers the surface of the semiconductor substrate 100 is first peeled off with a hydrofluoric acid solution or the like. Afterward, the gate insulating film 140 including SiO₂ is formed on the semiconductor substrate 100 to have a film thickness of 1.5 nm to 10 nm by dry oxidization using O₂ at 700° C. or RTA (Rapid Thermal Anneal) treatment. It is to be noted that H₂/O₂, N₂O, or NO mixed gas may be used as gas used for the dry oxidation in addition to O₂. In addition, the use of plasma-nitridation in forming the gate insulating film 140 also makes it possible to dope the SiO₂ film with nitrogen.

Next, a film of polysilicon is formed to have a film thickness of 50 nm to 150 nm by using low-pressure CVD in which SiH₄ gas is source gas and the film-forming temperature is 580° C. to 620° C. Afterward, anisotropic etching is performed on the formed film of polysilicon with a patterned resist used as a mask, forming the gate electrodes 131, 132, 133, and 134. For example, it is possible to use HBr or Cl-based gas for the anisotropic etching. For example, in a 40-nm node, the gate electrodes 131, 132, 133, and 134 may be formed by setting a gate width of about 40 nm to 50 nm.

It is to be noted that the gate electrodes 131, 132, 133, and 134 may be formed at the same time as a gate electrode of a transistor provided to a logic region or the like other than the region for forming the memory cell 10.

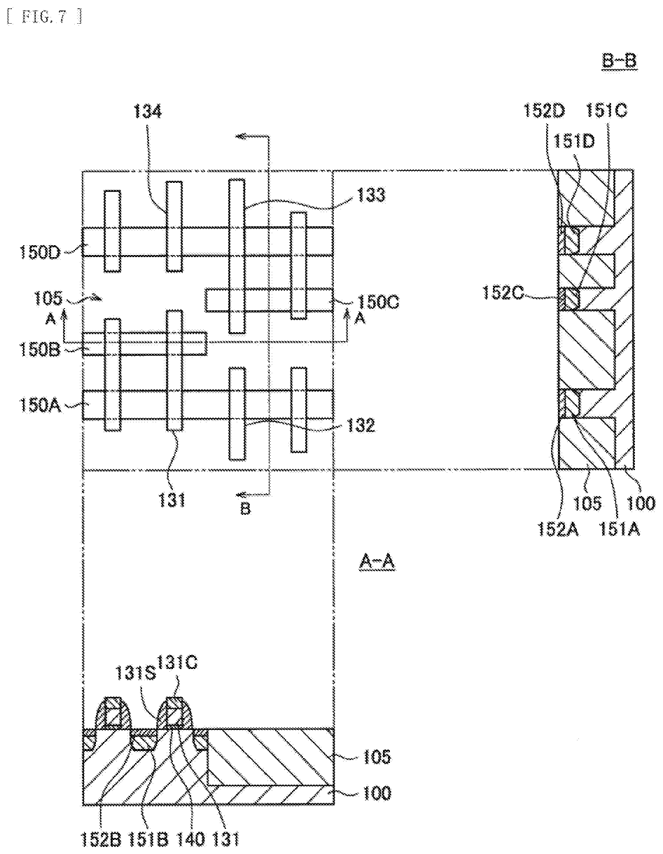

Next, as illustrated in FIG. 7, the sidewall insulating films 1315, 132S, 133S, and 1345 (the sidewall insulating films 132S, 133S, and 1345 are not illustrated) are formed on both side surfaces of the gate electrodes 131, 132, 133, and 134. Afterward, the source or drain regions 151A, 151D, 151B, and 151C are respectively formed in the p-type activation regions 150A and 150D and n-type activation regions 150B and 150C of the semiconductor substrate 100.

Specifically, arsenic (As) that is an n-type impurity is ion-implanted to each of the p-type activation regions 150A and 150D on both sides of the gate electrodes 131, 132, 133, and 134 with a concentration of 5 to 20×10¹³ atoms/cm² at 5 keV to 20 keV. It is to be noted that it is also possible to use phosphorus (P) as an n-type impurity. In addition, boron fluoride (BF₂) that is a p-type impurity is ion-implanted to each of the n-type activation regions 150B and 150C on both sides of the gate electrodes 131 and 133 with a concentration of 5 to 20×10¹³ atoms/cm² at 3 keV to 5 keV. This forms an LDD region in each of the p-type activation regions 150A and 150D and n-type activation regions 150B and 150C. Forming the LDD region allows a short channel effect to be suppressed. It is thus possible to suppress variations in FET characteristics.

Next, after a film of SiO₂ is formed to have a film thickness of 10 nm to 30 nm by plasma CVD, a film of Si₃N₄ is formed to have a film thickness of 30 nm to 50 nm by plasma CVD to form an insulating film for the sidewall. Afterward, the insulating film for the sidewall is subjected to anisotropic etching to form the sidewall insulating films 1315, 132S, 133S, and 134S on both sides of the gate electrodes 131, 132, 133, and 134.

Afterward, arsenic (As) that is an n-type impurity is ion-implanted to each of the p-type activation regions 150A and 150D on both sides of the gate electrodes 131, 132, 133, and 134 with a concentration of 1 to 2×10¹⁵ atoms/cm² at 20 keV to 50 keV. In addition, boron fluoride (BF₂) that is a p-type impurity is ion-implanted to each of the n-type activation regions 150B and 150C on both sides of the gate electrodes 131 and 133 with a concentration of 1 to 2×10¹⁵ atoms/cm² at 5 keV to 10 keV. This forms the source or drain regions 151A, 151D, 151B, and 151C on both sides of the gate electrodes 131, 132, 133, and 134. Further, RTA (Rapid Thermal Annealing) is performed at 1000° C. for 5 seconds to activate the ion-implanted n-type impurities and p-type impurities. This forms each FET on the semiconductor substrate 100. It is to be noted that it is also possible to activate the impurities by spike RTA to accelerate the activation of the introduced impurities and suppress the diffusion of the impurities.

Next, a film of Ni is formed to have a film thickness of 6 nm to 8 nm over the entire surface of the semiconductor substrate 100 by sputtering or the like. Afterward, RTA is performed at 300° C. to 450° C. for 10 seconds to 60 seconds to silicify (NiSi) Ni on Si. The Ni on the SiO₂ remains unreacted and the unreacted Ni on the SiO₂ is thus removed by using H₂SO₄/H₂O₂. This forms the conductive layers 131C, 132C, 133C, and 133C each including NiSi and the contact regions 152A, 152B, 152C, and 152D on the gate electrodes 131, 132, 133, and 134 and the source or drain regions 151A, 151B, 151C, and 151D (the conductive layers 132C, 133C, and 133C are not illustrated). It is to be noted that the conductive layers 131C, 132C, 133C, and 133C and the contact regions 152A, 152B, 152C, and 152D may be formed with CoSi₂ or NiSi by forming a film of Co or NiPt instead of Ni. The temperature at which RTA is performed in a case of forming a film of Co or NiPt may be appropriately set.

Next, as illustrated in FIG. 8, the planarization film 200 is formed over the entire surface of the semiconductor substrate 100 to embed each FET. Afterward, an opening is formed in the planarization film 200 and the lower electrode 111 is formed in the opening.

Specifically, a film of SiO₂ is formed on the semiconductor substrate 100 by using CVD or the like to have a film thickness of 100 nm to 500 nm and then planarized by CMP to form the planarization film 200.

It is to be noted that, although not illustrated, a linear layer including SiN may be formed on the semiconductor substrate 100 over the entire surface of the semiconductor substrate 100 before the planarization film 200 is formed. For example, the liner layer may be formed by forming a film of SiN to have a film thickness of 10 nm to 50 nm by using plasma CVD. It is also possible to form the liner layer as a layer that applies compression stress or tensile stress to the semiconductor substrate 100. Forming the liner layer makes it possible to etch the planarization film 200 under the condition that the etching selectivity between the planarization film 200 and the liner layer becomes high in a subsequent step. This makes it possible to perform etching with higher controllability.

Next, openings for exposing the source or drain regions 151A and 151B and gate electrode 133 and openings for exposing the source or drain regions 151C and 151D and gate electrode 131 are formed in the planarization film 200 by using anisotropic etching, which uses a resist patterned by lithography as a mask. It is possible to form openings each having, for example, a width of 60 nm and a depth of 200 nm. If each opening has an aspect ratio of about 20 at this time, it is possible to perform etching to form the opening and subsequently fill the opening by forming a film with no problem. For example, the use of fluorocarbon-based gas allows the anisotropic etching to be performed. In addition, the use of the above-described linear layer makes it possible to stop etching with favorable controllability.

Next, films of TiN each having a film thickness of 5 nm to 20 nm are formed on the source or drain regions 151A and 151B and the gate electrode 133 along the inner shape of the openings formed in the planarization film 200 by using sputtering by ALD, CVD, or IMP. The lower electrode 111 of the first ferroelectric capacitor 14 is formed. It is to be noted that it is also possible to use TaN, Ru, RuO₂, or the like instead of TiN as a material for forming the lower electrode 111.

Afterward, a resist is applied onto each of the formed lower electrodes 111 and etch-back is then performed under the condition that the resist and the lower electrode 111 have substantially the same etching selectivity. This retracts the lower electrode 111 from the opening surface of the opening. This makes it possible to form a recess by retracting the shoulders of the lower electrode 111 while leaving the lower electrode 111 on the bottom and side surface of the opening.

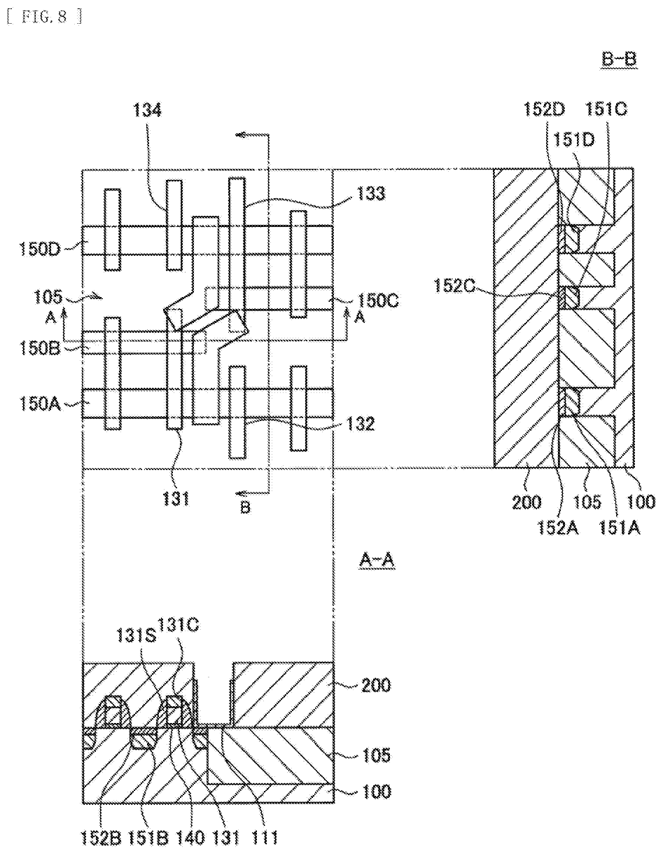

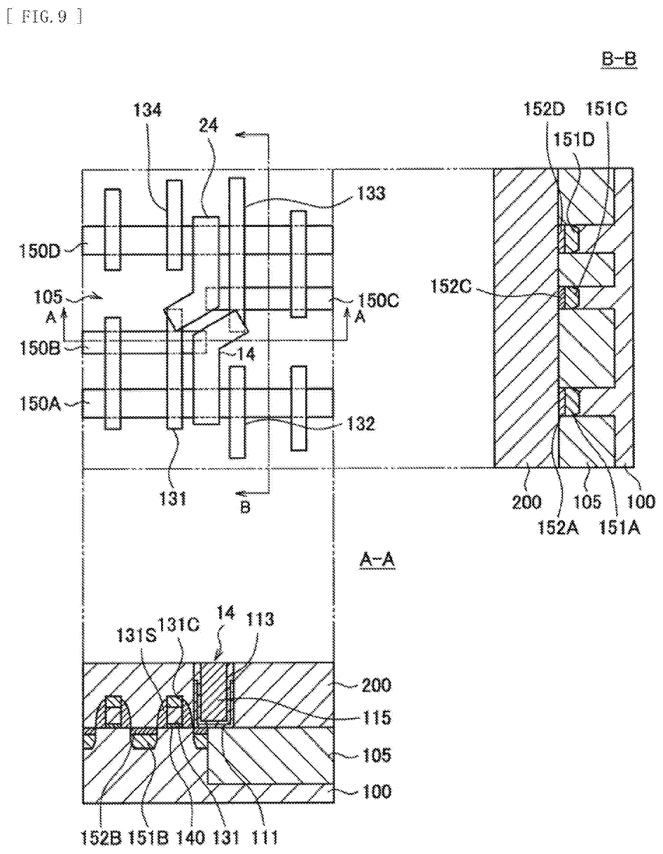

Next, as illustrated in FIG. 9, the ferroelectric film 113 is formed on the lower electrode 111 and the upper electrode 115 is further formed on the ferroelectric film 113 to form the first ferroelectric capacitor 14 in each opening.

Specifically, a film of hafnium oxide (HfOₓ) is formed on each lower electrode 111 by CVD or ALD along the inner shape of an opening to have a film thickness of 3 nm to 10 nm, thereby forming the ferroelectric film 113. The hafnium oxide (HfOₓ) is a high dielectric material. The opening is provided in the planarization film 200. It is to be noted that the hafnium oxide (HfOₓ) that is a high dielectric material is converted to a ferroelectric material by being subjected to annealing treatment in a subsequent step.

It is to be noted that it is also possible to use a high dielectric material such as zirconium oxide (ZrOₓ) or hafnium zirconium oxide (HfZrOₓ) instead of hafnium oxide. In addition, it is also possible to convert these high dielectric materials into ferroelectric materials by doping the high dielectric materials with lanthanum (La), silicon (Si), gadolinium (Gd), or the like. Further, it is also possible to use a perebskite-based ferroelectric material such as lead zirconate titanate (PZT) or strontium bismuth tantalate (SBT) as the ferroelectric film 113.

Afterward, a film of TiN is formed to have a film thickness of 5 nm to 20 nm on the ferroelectric film 113 by using CVD, ALD, sputtering, or the like to fill each opening formed in the planarization film 200, thereby forming each upper electrode 115. It is to be noted that it is also possible to use TaN, Ru, or RuO₂ as a material for forming the upper electrode 115. Next, crystallization annealing is performed to convert the HfOₓ included in the ferroelectric film 113 to a ferroelectric material.

Crystallization annealing to convert HfOₓ to a ferroelectric material may be performed in this step or another step (e.g., after CMP described below). It is possible to make any change in crystallization annealing, for example, within a range of 400° C. to 700° C. and the heat resistance range of another component such as NiSi or FET. Afterward, the ferroelectric film 113 and the upper electrode 115 excessively formed on the planarization film 200 are removed by performing CMP or full-surface etch-back.

This forms the first ferroelectric capacitor 14. Such a step allows the ferroelectric film 113 to be subjected to crystallization annealing at high temperature before a step of forming a wiring line such as the first wiring layer. This makes it possible to reduce heat loads on the wiring line such as the first wiring layer. In addition, the second ferroelectric capacitor 24 is formed in these steps of forming the first ferroelectric capacitor 14.

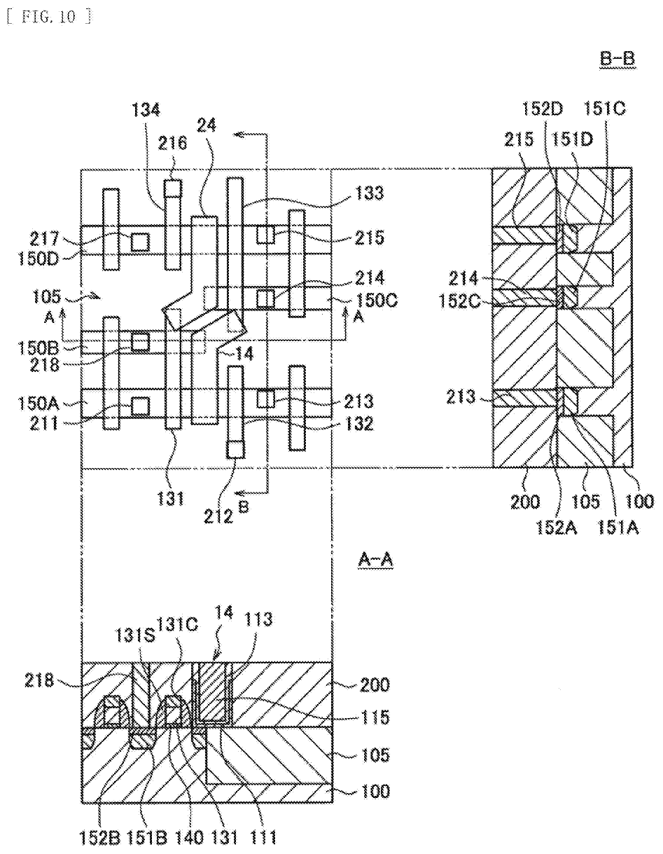

Next, as illustrated in FIG. 10, the first contacts 211, 212, 213, 214, 215, 216, 217, and 218 are formed.

Specifically, openings for exposing the predetermined source or drain regions 151A, 151B, 151C, and 151D and gate electrodes 132 and 134 are formed in the planarization film 200 by etching the planarization film 200. Subsequently, films of Ti and TiN are formed in the openings of the planarization film 200 by CVD or the like and films of W are further formed. Afterward, planarization is performed by CMP. This forms the first contacts 211, 212, 213, 214, 215, 216, 217, and 218 on the source or drain regions 151A, 151B, 151C, and 151D and gate electrodes 132 and 134.

It is to be noted that films of Ti and TiN may be formed by sputtering or the like using IMP. In addition, planarization may be performed by using full-surface etch-back instead of CMP. It is to be noted that the first contacts 211, 212, 213, 214, 215, 216, 217, and 218 may be formed at the same time as a contact of a transistor provided to a logic region or the like other than the region for forming the memory cell 10.

Next, as illustrated in FIG. 11, after the first interlayer insulating film 300 is formed over the entire surface of the semiconductor substrate 100, the first wiring layers 311, 312, 313, 314, 315, 316, 317, 318, and 319 are formed.

Specifically, a film of SiO₂ is formed to have a film thickness of 100 nm to 500 nm over the entire surface of the planarization film 200 by using CVD or the like and then planarized by CMP, thereby forming the first interlayer insulating film 300. Next, openings are formed by etching the first interlayer insulating film 300 for exposing the first contacts 211, 212, 213, 214, 215, 216, 217, and 218 and the upper electrodes of the first ferroelectric capacitor 14 and the second ferroelectric capacitor 24. Afterward, Cu or the like is used as a wiring line material to form each of the first wiring layers 311, 312, 313, 314, 315, 316, 317, 318, and 319 by using a damascene structure or a dual damascene structure. It is to be noted that each of the first wiring layers 311, 312, 313, 314, 315, 316, 317, 318, and 319 may also include Al or the like.

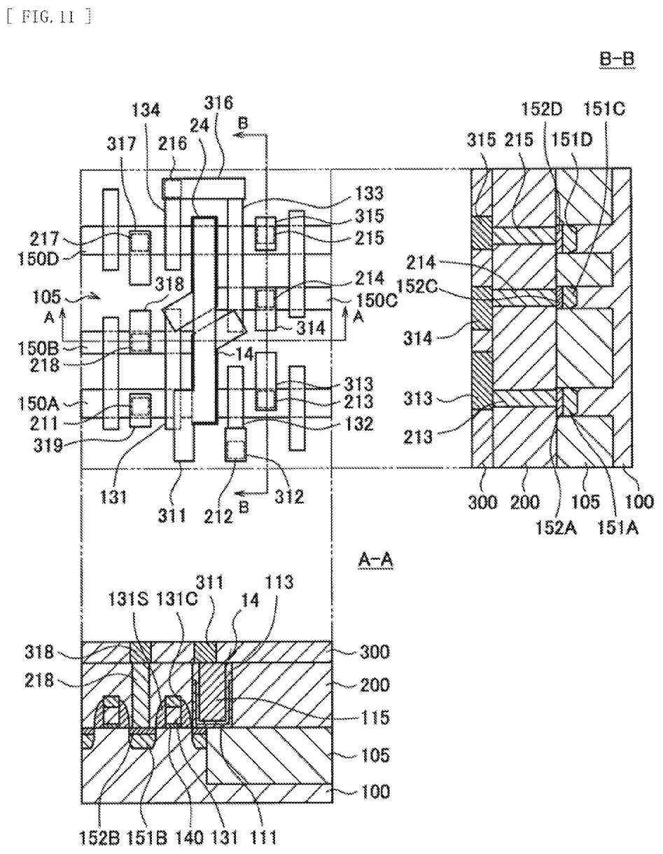

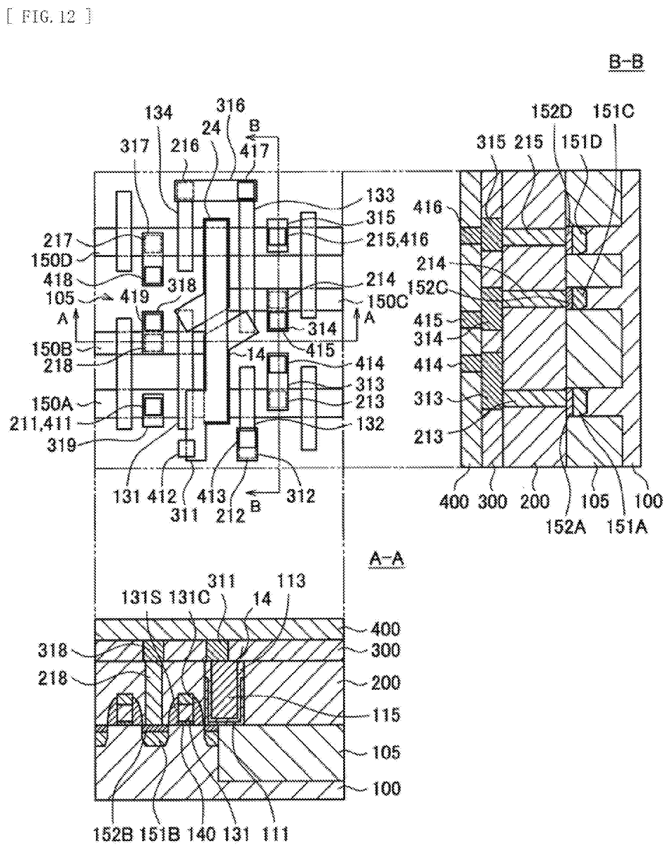

Next, as illustrated in FIG. 12, the second interlayer insulating film 400 is formed on the first interlayer insulating film 300 over the entire surface of the semiconductor substrate 100 and the second contacts 411, 412, 413, 414, 415, 416, 417, 418, and 419 are then formed.

Specifically, a film of SiO₂ is formed to have a film thickness of 100 nm to 500 nm over the entire surface of the first interlayer insulating film 300 by using CVD or the like and then planarized by CMP, thereby forming the second interlayer insulating film 400. Subsequently, the second interlayer insulating film 400 is etched to form openings for exposing the first wiring layers 312, 313, 314, 315, 316, 317, 318, and 319. Next, films of TiN are formed in the formed openings by CVD or the like and films of W are further formed. Afterward, planarization is performed by CMP to form the second contacts 411, 412, 413, 414, 415, 416, 417, 418, and 419. It is to be noted that a film of Ti may be formed by sputtering or the like using IMP. In addition, planarization may be performed by using full-surface etch-back instead of CMP.

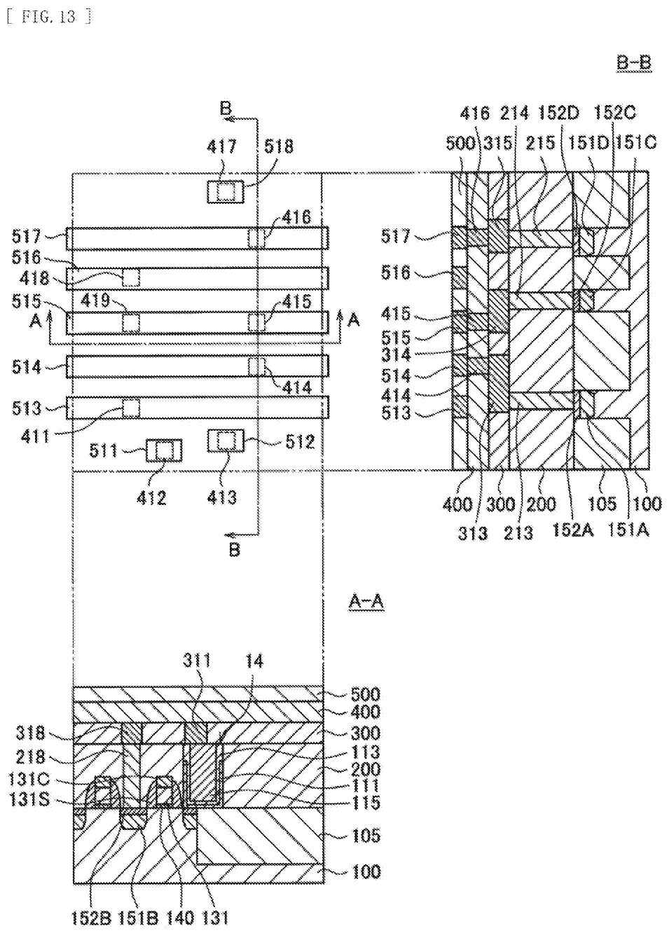

Next, as illustrated in FIG. 13, the third interlayer insulating film 500 is formed on the second interlayer insulating film 400 over the entire surface of the semiconductor substrate 100 and the second wiring layers 511, 512, 513, 514, 515, 516, 517, and 518 are then formed.

Specifically, a film of SiO₂ is formed to have a film thickness of 100 nm to 500 nm over the entire surface of the second interlayer insulating film 400 by using CVD or the like and then planarized by CMP, thereby forming the third interlayer insulating film 500. Next, the third interlayer insulating film 500 is etched to form openings for exposing the second contacts 411, 412, 413, 414, 415, 416, 417, 418, and 419. Afterward, a damascene structure or a dual damascene structure is used to form the second wiring layers 511, 512, 513, 514, 515, 516, 517, and 518 each including Cu or the like as a wiring line material. It is to be noted that each of the second wiring layers 511, 512, 513, 514, 515, 516, 517, and 518 may also include Al or the like.

The second wiring layer 513 is provided on the second contact 411 by being extended in the first direction and functions as the ground line GND. The second wiring layer 514 is provided on the second contact 414 by being extended in the first direction and functions as the first bit line BL1. The second wiring layer 515 is provided on the second contacts 415 and 419 by being extended in the first direction and functions as the power supply line PWR. The second wiring layer 516 is provided on the second contact 418 by being extended in the first direction and functions as the second bit line BL2. The second wiring layer 517 is provided on the second contact 416 by being extended in the first direction and functions as the ground line GND.

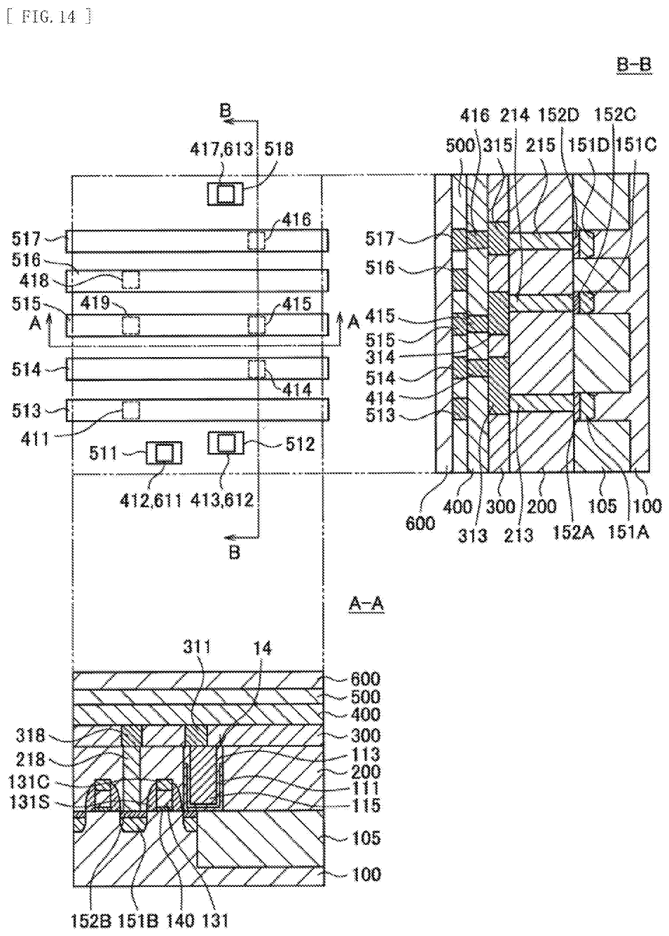

Next, as illustrated in FIG. 14, after the fourth interlayer insulating film 600 is formed on the third interlayer insulating film 500 over the entire surface of the semiconductor substrate 100, the third contacts 611, 612, and 613 are formed.

Specifically, a film of SiO₂ is formed to have a film thickness of 100 nm to 500 nm over the entire surface of the third interlayer insulating film 500 by using CVD or the like and then planarized by CMP, thereby forming the fourth interlayer insulating film 600. Subsequently, the fourth interlayer insulating film 600 is etched to form openings for exposing the second wiring layers 511, 512, and 518. Next, films of TiN are formed in the formed openings by CVD or the like and films of W are further formed. Afterward, planarization is performed by CMP to form the third contacts 611, 612, and 613. It is to be noted that a film of Ti may be formed by sputtering or the like using IMP. In addition, planarization may be performed by using full-surface etch-back instead of CMP.

Next, as illustrated in FIG. 15, after the fifth interlayer insulating film 700 is formed on the fourth interlayer insulating film 600 over the entire surface of the semiconductor substrate 100, the third wiring layers 711 and 712 are formed.

Specifically, a film of SiO₂ is formed to have a film thickness of 100 nm to 500 nm over the entire surface of the fourth interlayer insulating film 600 by using CVD or the like and then planarized by CMP, thereby forming the fifth interlayer insulating film 700. Next, after the fifth interlayer insulating film 700 is etched to form openings for exposing the third contacts 611, 612, and 613, the third wiring layers 711 and 712 each including Cu or the like as a wiring line material are formed by using a damascene structure or a dual damascene structure. It is to be noted that the third wiring layers 711 and 712 may each include Al or the like.

The third wiring layer 711 is provided on the third contact 611 by being extended in the second direction orthogonal to the first direction and function as the plate line PL. The third wiring layer 712 is provided on the third contacts 612 and 613 by being extended in the second direction orthogonal to the first direction and function as the word line WL.

The above-described steps make it possible to form the memory cell 10 including the semiconductor device 1 according to the present embodiment.

### 4. Operation Example

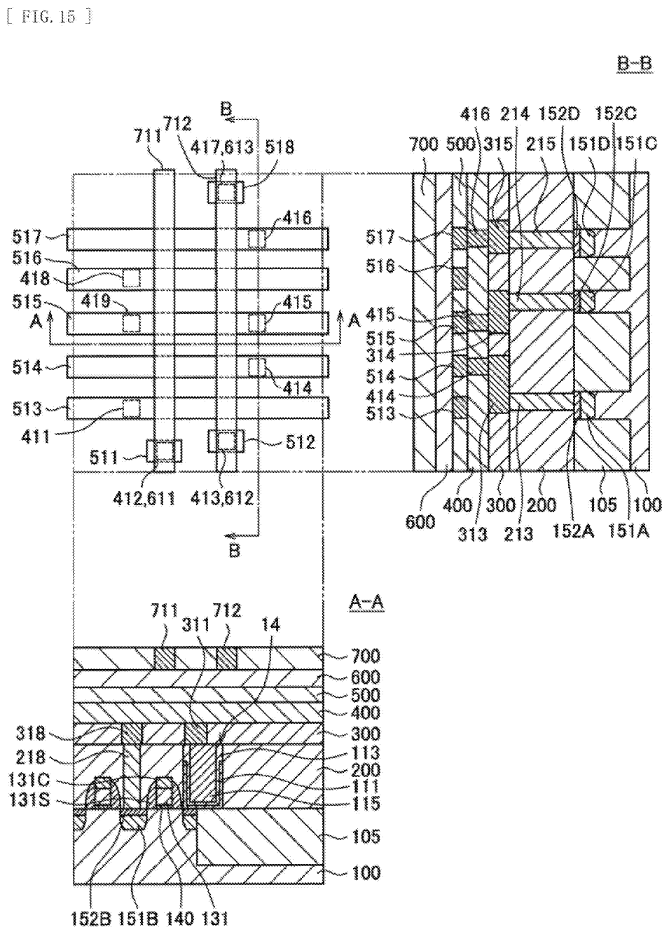

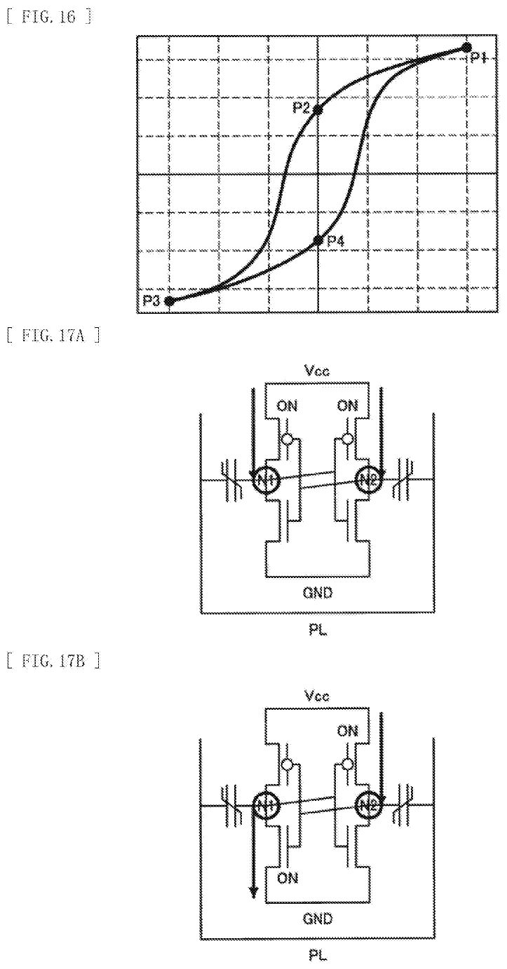

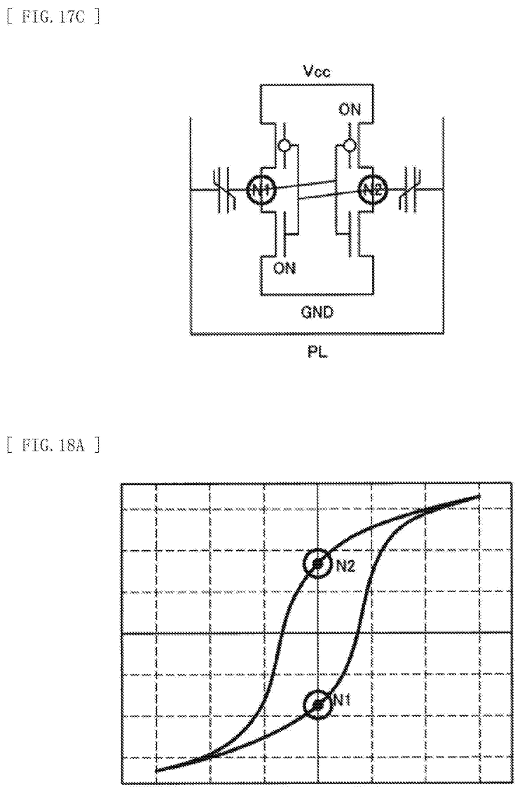

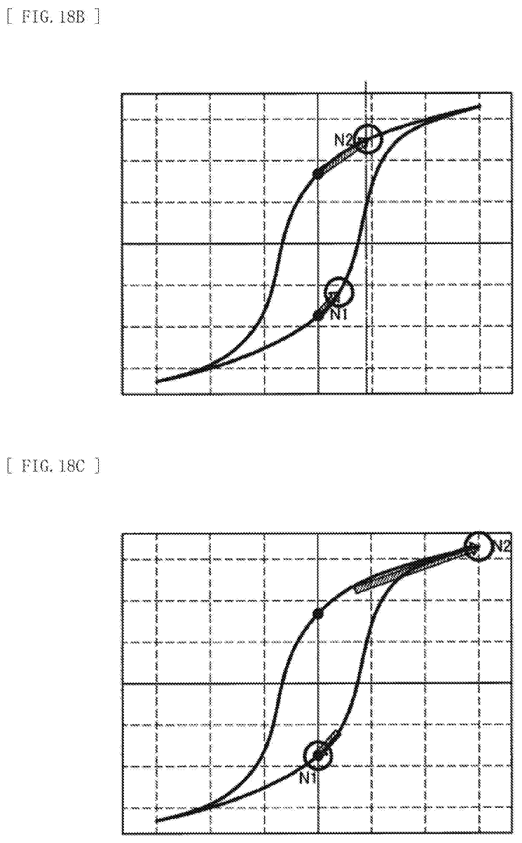

Next, with reference to FIGS. 16 to 18C, an operation example of the memory cell 10 described above is described. FIG. 16 is a graph illustrating an example of hysteresis curves indicating the relationships between states of the first storage node N1 and second storage node N2 and the electric potentials. FIGS. 17A to 17C are explanatory diagrams each describing transition of the state of the memory cell 10 at the time of restoration. FIGS. 18A to 18C are explanatory diagrams each describing transition of the states of the first storage node N1 and second storage node N2 at the time of restoration. FIGS. 16 and 18A to 18C each illustrate an electric potential on the horizontal axis and the amount of polarization of the first ferroelectric capacitor 14 or second ferroelectric capacitor 24 on the vertical axis.

Table 1 below is a table illustrating an example of a voltage (unit: V) applied to each wiring line of the memory cell 10 at the time of each operation. In addition, Table 1 also illustrates the electric potentials of the first storage node N1 and second storage node N2. It is to be noted that “Vcc” represents a power supply voltage, “Vw” represents the write voltage (voltage allowing the polarized state of each ferroelectric film to be inverted) of each of the first ferroelectric capacitor and second ferroelectric capacitor, and “OFF” represents that the corresponding wiring line is put in the floating state in Table 1.

TABLE 1

| | in operation | time of | | time of | time of |
|---|---|---|---|---|---|
| | on standby | storage | | hibernation | restoration |
| word line WL | OFF | OFF | OFF | OFF | OFF |
| plate line PL | 0 | Vw | 0 | 0 | 0 |
| power supply | Vcc | Vw | Vw | 0 | Vcc |
| line PWR | | | | | |
| ground line GND | 0 | 0 | 0 | 0 | 0 |
| first storage node | 0 | 0 | 0 | 0 | 0 |
| N1 | | | | | |
| second storage | Vcc | Vw | Vw | 0 | Vcc |
| node N2 | | | | | |

For example, when the memory cell 10 is in operation or on standby, the word line WL is put in the floating state, the power supply line PWR has Vcc, the ground line GND has 0 V, and the plate line PL has 0 V as illustrated in Table 1. At this time, the memory cell 10 is able to control the states (i.e., electric potentials) of the first storage node N1 and second storage node N2 in an operation similar to that of SRAM by controlling the electric potentials of the word line WL, first bit line BL1, and second bit line BL2.

Here, an operation of storing the states of the first storage node N1 and second storage node N2 in the first ferroelectric capacitor 14 and second ferroelectric capacitor 24 before power supply is stopped is described.

It is to be noted that the electric potential of the first storage node N1 is considered to be 0 V and the electric potential of the second storage node N2 is considered to be Vcc as the states of the first storage node N1 and second storage node N2. At this time, the first storage node N1 is put in the state of P4 on a hysteresis curve in FIG. 16 and the second storage node N2 is put in the state of P1 on a hysteresis curve in FIG. 16.

At the time of storage in the first ferroelectric capacitor 14 and second ferroelectric capacitor 24, Vw is first applied to the power supply line PWR and plate line PL as illustrated in Table 1. At this time, the first storage node N1 is put in the state of P3 on a hysteresis curve in FIG. 16 and the second storage node N2 is put in the state of P2 on a hysteresis curve in FIG. 16. Next, while the electric potential of the power supply line PWR is kept at Vw, the electric potential of the plate line PL is set at 0 V. At this time, the first storage node N1 is put in the state of P4 on a hysteresis curve in FIG. 16 and the second storage node N2 is put in the state of P1 on a hysteresis curve in FIG. 16.

In a case where power supply is then stopped to set the electric potentials of all the wiring lines at 0 V and set all the wiring lines in the hibernation state, the first storage node N1 is put in the state of P4 on the hysteresis curve in FIG. 16 and the second storage node N2 is put in the state of P2 on the hysteresis curve in FIG. 16. This allows the memory cell 10 to retain information by using the remanent polarization of the first ferroelectric capacitor 14 and second ferroelectric capacitor 24 even at the time of hibernation with no power supply.

Subsequently, when the memory cell 10 is restored from the hibernation state, the same operation condition as the operation condition applied when the memory cell 10 is in operation or on standby is applied to allow the first storage node N1 and the second storage node N2 to be restored to the states before the hibernation.

An operation at the time of restoration from the hibernation state is described as follows with reference to FIGS. 17A to 17C and 18A to 18C.

Specifically, as illustrated in Table 1, the word line WL is put in the floating state, Vcc is applied to the power supply line PWR, and 0 V is applied to the ground line GND and the plate line PL.

As illustrated in FIG. 17A, this causes the p-type FET 12 and the p-type FET 22 to each have a gate voltage of 0 V, putting the p-type FET 12 and the p-type FET 22 in the on states. The first storage node N1 and the second storage node N2 are each supplied with an electric charge from the power supply line PWR. The first storage node N1 and the second storage node N2 at this time transition from the states illustrated in FIG. 18A to the states illustrated in FIG. 18B and each have the electric potential changed to the electric potential of Vcc. The first storage node N1, however, has larger load capacitance and thus has a more gradual change in electric potential than that of the second storage node N2.

Here, in a case where the electric potential of the second storage node N2 reaches a threshold voltage Vth of the n-type FET 13, the n-type FET 13 is put in the on state as illustrated in FIG. 17B. This causes the electric charges accumulated in the first storage node N1 to be discharged to the ground line GND. The electric potential of the first storage node N1 thus transitions from the state illustrated in FIG. 18B to the state illustrated in FIG. 18C and is brought back to 0 V. In contrast, the n-type FET 23 remains in the on state and the second storage node N2 thus keeps on being supplied with electric charges. The electric potential of the second storage node N2 keeps on changing to Vcc.

The operation state of the memory cell 10 like this continues until the electric potential of the first storage node N1 and the electric potential of the second storage node N2 are each stable as illustrated in FIG. 17C. This finally causes the electric potential of the first storage node N1 to be stable at 0 V and the electric potential of the second storage node N2 to be stable at Vcc as illustrated in FIG. 18C. Such an operation allows the memory cell 10 to restore the states of the first storage node N1 and second storage node N2 to the states before hibernation.

It is to be noted that the above has described the case where the electric potential of the first storage node N1 is 0 V and the electric potential of the second storage node N2 is Vcc. However, it is also possible to similarly perform a storage operation and a restoration operation in a case where the electric potential of the first storage node N1 is Vcc and the electric potential of the second storage node N2 is 0 V.

The above-described operation allows the memory cell 10 including the semiconductor device 1 according to the present embodiment to perform a high-speed operation similar to that of SRAM at the time of power supply. In addition, the memory cell 10 is able to store information in the first ferroelectric capacitor 14 and the second ferroelectric capacitor 24 even at the time of hibernation with power supply stopped and restore the information from the first ferroelectric capacitor 14 and the second ferroelectric capacitor 24 at the time of restoration. This allows the memory cell 10 to operate as a non-volatile memory that is able to retain information even at the time of hibernation with power supply stopped, making it possible to further reduce power to be consumed.

### 5. Application Example

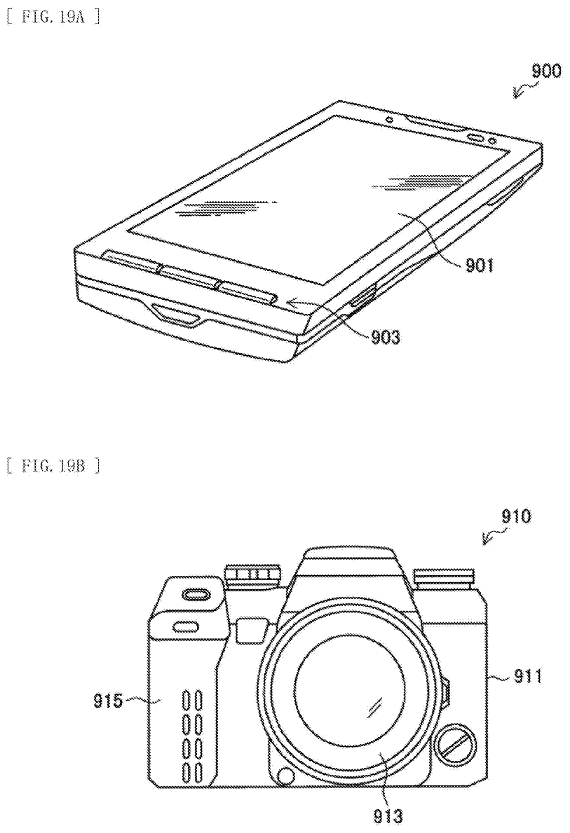

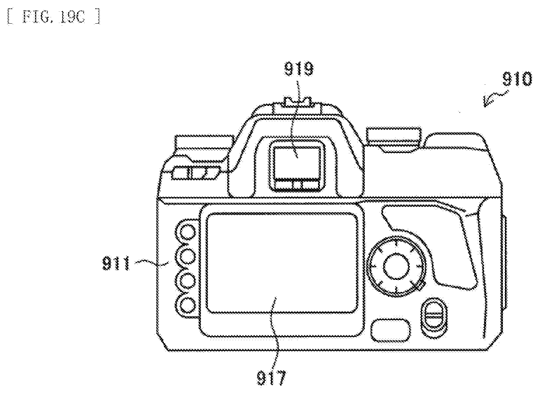

Next, an electronic apparatus according to an embodiment of the present disclosure is described. The electronic apparatus according to the embodiment of the present disclosure includes a variety of electronic apparatuses mounted with circuits each including the above-described semiconductor device 1. Examples of such an electronic apparatus according to the present embodiment are described with reference to FIGS. 19A to 19C. Each of FIGS. 19A to 19C is an external view of an example of the electronic apparatus according to the present embodiment.

For example, the electronic apparatus according to the present embodiment may be an electronic apparatus such as a smartphone. Specifically, as illustrated in FIG. 19A, a smartphone 900 includes a display unit 901 that displays various kinds of information and an operation unit 903 including a button or the like that receives an operation input from a user. Here, a circuit mounted on the smartphone 900 may be provided with the above-described semiconductor device 1.

For example, the electronic apparatus according to the present embodiment may be an electronic apparatus such as a digital camera. Specifically, as illustrated in FIGS. 19B and 19C, a digital camera 910 includes a main body (camera body) 911, an interchangeable lens unit 913, a grip unit 915 that is gripped by a user during photography, a monitor unit 917 that displays various kinds of information, and EVF (Electronic View Finder) 919 that displays a through image which is observed by a user during photography. It is to be noted that FIG. 19B is an external view in which the digital camera 910 is viewed from the front (i.e., subject side). FIG. 19C is an external view in which the digital camera 910 is viewed from the back (i.e., photographer side). Here, a circuit mounted on the digital camera 910 may be provided with the above-described semiconductor device 1.

The electronic apparatus according to the present embodiment is not, however, limited to the above-described examples. The electronic apparatus according to the present embodiment may be an electronic apparatus of any field. Examples of such an electronic apparatus include a glasses-shaped wearable device, HMD (Head Mounted Display), a television apparatus, an electronic book, PDA (Personal Digital Assistant), a notebook personal computer, a video camera, a game console, or the like.

A preferred embodiment(s) of the present disclosure has/have been described above in detail with reference to the accompanying drawings, but the technical scope of the present disclosure is not limited to such an embodiment(s). It is apparent that a person having ordinary skill in the art of the present disclosure may arrive at various alterations and modifications within the scope of the technical idea described in the appended claims and it is understood that such alterations and modifications naturally fall within the technical scope of the present disclosure.

In addition, the effects described herein are merely illustrative and exemplary, but not limitative. That is, the technology according to the present disclosure may exert other effects that are apparent to those skilled in the art from the description herein in addition to the above-described effects or in place of the above-described effects.

It is to be noted that the following configurations also fall within the technical scope of the present disclosure.

(1)

A semiconductor device including:

a first inverting circuit including n-type FET and p-type FET;

a second inverting circuit including n-type FET and p-type FET, the second inverting circuit having an output coupled to an input of the first inverting circuit and having an input coupled to an output of the first inverting circuit;

a first ferroelectric capacitor that has one of electrodes coupled to the input of the first inverting circuit;

a second ferroelectric capacitor that has one of electrodes coupled to the input of the second inverting circuit; and

a plate line that is coupled to another of the electrodes of the first ferroelectric capacitor and another of the electrodes of the second ferroelectric capacitor.

(2)

The semiconductor device according to (1), in which the n-type FETs and the p-type FETs of the first inverting circuit and the second inverting circuit are provided to respective p-type or n-type activation regions that extend in a first direction in parallel with each other.

(3)

The semiconductor device according to (2), in which the n-type FETs and the p-type FETs of the first inverting circuit and the second inverting circuit are electrically coupled to each other by gate electrodes that extend in a second direction orthogonal to the first direction.

(4)

The semiconductor device according to (3), in which

a first shared contact is provided from the gate electrode of the first inverting circuit over each of the p-type or n-type activation regions provided with the n-type FET and the p-type FET of the second inverting circuit, and

a second shared contact is provided from the gate electrode of the second inverting circuit over each of the p-type or n-type activation regions provided with the n-type FET and the p-type FET of the first inverting circuit.

(5)

The semiconductor device according to (4), in which the first ferroelectric capacitor is provided in the first shared contact and the second ferroelectric capacitor is provided in the second shared contact.

(6)

The semiconductor device according to (5), in which the first ferroelectric capacitor and the second ferroelectric capacitor are each provided in a shape of a stacked cylinder.

(7)

The semiconductor device according to (5) or (6), in which the first shared contact and the second shared contact each have a bent planar shape.

(8)

The semiconductor device according to any one of (5) to (7), in which the plate line is provided on the first shared contact and the second shared contact, the plate line extending in the second direction.

(9)

The semiconductor device according to any one of (4) to (8), in which, in each of the first inverting circuit and the second inverting circuit, a power supply line is electrically coupled to one of a source or a drain of the p-type FET, one of a source or a drain of the n-type FET is electrically coupled to another of the source or the drain of the p-type FET, and a ground line is electrically coupled to another of the source or the drain of the n-type FET.

(10)

The semiconductor device according to (9), in which the power supply line and the ground line are provided by being extended in the first direction.

(11)

The semiconductor device according to any one of (4) to (10), further including:

first selection FET that has one of a source or a drain electrically coupled to the other of the electrodes of the first ferroelectric capacitor; and

second selection FET that has one of a source or a drain electrically coupled to the other of the electrodes of the second ferroelectric capacitor.

(12)

The semiconductor device according to (11), in which the first selection FET and the second selection FET include n-type FETs that are provided in the respective p-type activation regions provided with the n-type FETs of the first inverting circuit and the second inverting circuit.

(13)

The semiconductor device according to (12), in which

the first selection FET is provided on a side opposite to the n-type FET of the first inverting circuit with the second shared contact interposed therebetween, and

the second selection FET is provided on a side opposite to the n-type FET of the second inverting circuit with the first shared contact interposed therebetween.

(14)

The semiconductor device according to any one of (11) to (13), in which a word line is electrically coupled to gates of the first selection FET and the second selection FET, the word line extending in the second direction.

(15)

The semiconductor device according to any one of (11) to (14), in which a first bit line or a second bit line extending in the first direction is electrically coupled to another of the source or the drain of each of the first selection FET and the second selection FET.

(16)

An electronic apparatus including

a semiconductor device including
a first inverting circuit including n-type FET and p-type FET,
a second inverting circuit including n-type FET and p-type FET, the second inverting circuit having an output coupled to an input of the first inverting circuit and having an input coupled to an output of the first inverting circuit,
a first ferroelectric capacitor that has one of electrodes coupled to the input of the first inverting circuit,
a second ferroelectric capacitor that has one of electrodes coupled to the input of the second inverting circuit, and
a plate line that is coupled to another of the electrodes of the first ferroelectric capacitor and another of the electrodes of the second ferroelectric capacitor.

### REFERENCE SIGNS LIST

1 semiconductor device
10 memory cell
11 first inverting circuit
12 p-type FET
13 n-type FET
14 first ferroelectric capacitor
15 first selection FET
21 second inverting circuit
22 p-type FET
23 n-type FET
24 second ferroelectric capacitor
25 second selection FET
PWR power supply line
GND ground line
PL plate line
WL word line
BL1 first bit line
BL2 second bit line

1. A semiconductor device comprising:
a first inverting circuit including n-type FET and p-type FET;
a second inverting circuit including n-type FET and p-type FET, the second inverting circuit having an output coupled to an input of the first inverting circuit and having an input coupled to an output of the first inverting circuit;
a first ferroelectric capacitor that has one of electrodes coupled to the input of the first inverting circuit;
a second ferroelectric capacitor that has one of electrodes coupled to the input of the second inverting circuit; and
a plate line that is coupled to another of the electrodes of the first ferroelectric capacitor and another of the electrodes of the second ferroelectric capacitor.

2. The semiconductor device according to claim 1, wherein the n-type FETs and the p-type FETs of the first inverting circuit and the second inverting circuit are provided to respective p-type or n-type activation regions that extend in a first direction in parallel with each other.

3. The semiconductor device according to claim 2, wherein the n-type FETs and the p-type FETs of the first inverting circuit and the second inverting circuit are electrically coupled to each other by gate electrodes that extend in a second direction orthogonal to the first direction.

4. The semiconductor device according to claim 3, wherein
a first shared contact is provided from the gate electrode of the first inverting circuit over each of the p-type or n-type activation regions provided with the n-type FET and the p-type FET of the second inverting circuit, and
a second shared contact is provided from the gate electrode of the second inverting circuit over each of the p-type or n-type activation regions provided with the n-type FET and the p-type FET of the first inverting circuit.

5. The semiconductor device according to claim 4, wherein the first ferroelectric capacitor is provided in the first shared contact and the second ferroelectric capacitor is provided in the second shared contact.

6. The semiconductor device according to claim 5, wherein the first ferroelectric capacitor and the second ferroelectric capacitor are each provided in a shape of a stacked cylinder.

7. The semiconductor device according to claim 5, wherein the first shared contact and the second shared contact each have a bent planar shape.

8. The semiconductor device according to claim 5, wherein the plate line is provided on the first shared contact and the second shared contact, the plate line extending in the second direction.

9. The semiconductor device according to claim 4, wherein, in each of the first inverting circuit and the second inverting circuit, a power supply line is electrically coupled to one of a source or a drain of the p-type FET, one of a source or a drain of the n-type FET is electrically coupled to another of the source or the drain of the p-type FET, and a ground line is electrically coupled to another of the source or the drain of the n-type FET.

10. The semiconductor device according to claim 9, wherein the power supply line and the ground line are provided by being extended in the first direction.

11. The semiconductor device according to claim 4, further comprising:
first selection FET that has one of a source or a drain electrically coupled to the other of the electrodes of the first ferroelectric capacitor; and
second selection FET that has one of a source or a drain electrically coupled to the other of the electrodes of the second ferroelectric capacitor.

12. The semiconductor device according to claim 11, wherein the first selection FET and the second selection FET include n-type FETs that are provided in the respective p-type activation regions provided with the n-type FETs of the first inverting circuit and the second inverting circuit.

13. The semiconductor device according to claim 12, wherein
the first selection FET is provided on a side opposite to the n-type FET of the first inverting circuit with the second shared contact interposed therebetween, and
the second selection FET is provided on a side opposite to the n-type FET of the second inverting circuit with the first shared contact interposed therebetween.

14. The semiconductor device according to claim 11, wherein a word line is electrically coupled to gates of the first selection FET and the second selection FET, the word line extending in the second direction.

15. The semiconductor device according to claim 11, wherein a first bit line or a second bit line extending in the first direction is electrically coupled to another of the source or the drain of each of the first selection FET and the second selection FET.

16. An electronic apparatus comprising
a semiconductor device including
a first inverting circuit including n-type FET and p-type FET,
a second inverting circuit including n-type FET and p-type FET, the second inverting circuit having an output coupled to an input of the first inverting circuit and having an input coupled to an output of the first inverting circuit,
a first ferroelectric capacitor that has one of electrodes coupled to the input of the first inverting circuit,
a second ferroelectric capacitor that has one of electrodes coupled to the input of the second inverting circuit, and
a plate line that is coupled to another of the electrodes of the first ferroelectric capacitor and another of the electrodes of the second ferroelectric capacitor.
